(19) United States
(12) Patent Application Publication
(10) Pub. No.: US 2026/0255760 A1
(43) Pub. Date: Aug. 27, 2026

(54) LED DEVICE AND LED ASSEMBLY

(71) Applicant: WUHU JUFEI OPTOELECTRONICS TECHNOLOGY CO., LTD, Wuhu, Anhui (CN)

(72) Inventors: Youpu KE, Wuhu (CN); Meide LIU, Wuhu (CN); Gang HE, Wuhu (CN); Huiping LIU, Wuhu (CN); Donghan WEI, Wuhu (CN); Yunhua LI, Wuhu (CN); Junxia SITU, Wuhu (CN); Pingru SUN, Wuhu (CN); Qingqing TAN, Wuhu (CN)

(73) Assignee: WUHU JUFEI OPTOELECTRONICS TECHNOLOGY CO., LTD, Wuhu, Anhui (CN)

(21) Appl. No.: 19/160,237

(22) PCT Filed: Feb. 28, 2024
(86) PCT No.: PCT/CN2024/079078

§ 371 Date: Aug. 27, 2025

(30) Foreign Application Priority Data
Feb. 28, 2023 (CN) 202310177965.7
Feb. 28, 2023 (CN) 202310201348.6
Apr. 14, 2023 (CN) 202320845789.5
Apr. 26, 2023 (CN) 202310478094.2

(51) Int. Cl. H10H 29/851; H10H 20/811; H10H 20/841; H10H 20/854; H10H 20/856; H10H 20/857; H10H 29/85; H10H 29/854; H10H 29/856

(52) U.S. Cl. CPC H10H 29/8513; H10H 20/811; H10H 20/841; H10H 20/854; H10H 20/856; H10H 20/857; H10H 29/854; H10H 29/856; H10H 29/857

(57) ABSTRACT

The present application relates to an LED device and LED assembly, comprising light-emitting units and an encapsulation layer disposed on the light-emitting units to cover the light-emitting units to provide protection, wherein light emitted by the light-emitting units exit through the encapsulation layer.

### TECHNICAL FIELD

The present application relates to the field of LEDs (Light Emitting Diodes), and particularly to an LED device and an LED assembly.

### BACKGROUND

LEDs are widely used in various lighting fields, optical signals, and other areas. An LED chip generally consists of two semiconductor layers and an active layer located between them. The two semiconductor layers are a P-type semiconductor layer and a N-type semiconductor layer, with the active layer serving as the light-emitting layer positioned between the P-type and N-type semiconductor layers. The material of the P-type semiconductor layer is typically a semiconductor doped with aluminum or gallium, while the N-type semiconductor material is usually a semiconductor doped with phosphorus. The active layer is generally made of gallium arsenide or gallium arsenide. Due to the materials and fabrication processes used in LED chips, they are relatively fragile and prone to damage when employed as light-emitting units in various lighting and optical signal applications, resulting in poor reliability.

### SUMMARY

### Technical Problem

In view of the shortcomings of the prior art, an object of the present application is to provide an LED device and an LED assembly, aiming to address the issues in related art where LED chips are fragile, easily damaged during application, and exhibit poor reliability.

### Technical Solution

To solve the above problems, the present application provides an LED device, comprising a light-emitting unit and an encapsulation layer disposed on the light-emitting units to cover the light-emitting units. The light emitted by the light-emitting unit exits through the encapsulation layer.

Based on the same inventive concept, the present application further provides an LED assembly, which comprises a circuit board and the aforementioned LED device. The LED device is disposed on the circuit board.

### Advantageous Effects

The LED device and LED assembly provided in the present application comprise light-emitting units, for example the light-emitting units comprise LED chips, and an encapsulation layer disposed on the light-emitting units to cover the light-emitting units, allowing light emitted by the unit to exit through the encapsulation layer. By encapsulating the light-emitting units by the encapsulation layer to provide protection, the reliability of the device is improved.

### BRIEF DESCRIPTION OF DRAWINGS

FIG. 1-1 shows the spectral schematic of mainstream light sources in related art;

FIG. 1-2 shows the spectral schematic of a conventional Ra90 light source in related art;

FIG. 1-3 shows the comparative spectral schematic of mainstream light sources, conventional Ra90 light sources, and natural light in related art;

FIG. 2 shows the first structural schematic of the LED device provided in Embodiment 1 of the present application;

FIG. 3-1 shows the second structural schematic of the LED device provided in Embodiment 1 of the present application;

FIG. 3-2 shows the third structural schematic of the LED device provided in Embodiment 1 of the present application;

FIG. 3-3 shows the fourth structural schematic of the LED device provided in

Embodiment 1 of the present application;

FIG. 3-4 shows the fifth structural schematic of the LED device provided in Embodiment 1 of the present application;

FIG. 3-5 shows the sixth structural schematic of the LED device provided in Embodiment 1 of the present application;

FIG. 4-1 shows the seventh structural schematic of the LED device provided in Embodiment 1 of the present application;

FIG. 4-2 shows the eighth structural schematic of the LED device provided in Embodiment 1 of the present application;

FIG. 4-3 shows the ninth structural schematic of the LED device provided in Embodiment 1 of the present application;

FIG. 5-1 shows the spectral schematic of the combined blue LED chip units provided in Embodiment 1 of the present application;

FIG. 5-2 shows the spectral schematic of the LED device provided in Embodiment 1 of the present application at a color temperature of 5000K;

FIG. 5-3 shows the Rf-Rg schematic of the LED device provided in Embodiment 1 of the present application;

FIG. 5-4 shows the Rf hue schematic provided in Embodiment 1 of the present application;

FIG. 5-5 shows the color vector schematic of an existing LED device provided in Embodiment 1 of the present application;

FIG. 5-6 is a schematic diagram of the color vector of the LED device provided in Embodiment 1 of the present application;

FIG. 5-7 is a schematic diagram comparing the spectra of the LED device provided in Embodiment 1 of the present application;

FIG. 5-8 is a schematic diagram of the spectrum of the LED device provided in Embodiment 1 of the present application at a color temperature of 1700K;

FIG. 5-9 is a schematic diagram of the spectrum of the LED device provided in Embodiment 1 of the present application at a color temperature of 2700K;

FIG. 5-10 is a schematic diagram of the spectrum of the LED device provided in

Embodiment 1 of the present application at a color temperature of 3000K;

FIG. 5-11 is a schematic diagram of the spectrum of the LED device provided in Embodiment 1 of the present application at a color temperature of 4000K;

FIG. 5-12 is a schematic diagram of the spectrum of the LED device provided in Embodiment 1 of the present application at a color temperature of 5700K;

FIG. 5-13 is a schematic diagram of the spectrum of the LED device provided in Embodiment 1 of the present application at a color temperature of 6500K;

FIG. 5-14 is a schematic diagram of the spectrum of the LED device provided in Embodiment 1 of the present application at a color temperature of 13000K;

FIG. 6-1 is the first schematic structural diagram of the LED device provided in Embodiment 2 of the present application;

FIG. 6-2 is the second schematic structural diagram of the LED device provided in

Embodiment 2 of the present application;

FIG. 6-3 is the third schematic structural diagram of the LED device provided in

Embodiment 2 of the present application;

FIG. 6-4 is a schematic diagram of the spectrum after combining the blue LED chipset provided in Embodiment 2 of the present application;

FIG. 6-5 is a schematic diagram of the spectrum of the LED device provided in Embodiment 2 of the present application at a color temperature of 5000K;

FIG. 6-6 is a schematic diagram comparing the spectra of the LED device provided in Embodiment 2 of the present application;

FIG. 6-7 is an Rf-Rg schematic diagram of the LED device provided in Embodiment 2 of the present application;

FIGS. 6-8 illustrate the Rf tone diagram provided in Embodiment 2 of the present application;

FIG. 6-9 shows the spectral diagram of the LED device provided in Embodiment 2 of the present application at a color temperature of 2700K;

FIG. 6-10 shows the spectral diagram of the LED device provided in Embodiment 2 of the present application at a color temperature of 3000K;

FIG. 6-11 shows the spectral diagram of the LED device provided in Embodiment 2 of the present application at a color temperature of 4000K;

FIG. 6-12 shows the spectral diagram of the LED device provided in Embodiment 2 of the present application at a color temperature of 5700K;

FIG. 6-13 shows the spectral diagram of the LED device provided in Embodiment 2 of the present application at a color temperature of 6500K;

FIG. 6-14 shows the fourth schematic structural diagram of the LED device provided in Embodiment 2 of the present application;

FIG. 7-1 is a schematic structural diagram of an LED device provided in Embodiment 3 of the present application;

FIG. 7-2 shows another schematic structural diagram of the LED device provided in Embodiment 3 of the present application;

FIG. 8-1 shows the first schematic structural diagram of the LED device provided in Embodiment 4 of the present application;

FIG. 8-2 shows the second schematic structural diagram of the LED device provided in Embodiment 4 of the present application;

FIG. 8-3 shows the third schematic structural diagram of the LED device provided in Embodiment 4 of the present application;

FIG. 8-4 shows the fourth schematic structural diagram of the LED device provided in Embodiment 4 of the present application;

FIG. 8-5 shows the fifth schematic structural diagram of the LED device provided in Embodiment 4 of the present application;

FIG. 8-6 shows the sixth schematic structural diagram of the LED device provided in Embodiment 4 of the present application;

FIG. 8-7 shows the seventh schematic structural diagram of the LED device provided in Embodiment 4 of the present application;

FIG. 8-8 shows the eighth schematic structural diagram of the LED device provided in Embodiment 4 of the present application;

FIGS. 8-9 illustrate the structural schematic of the light-emitting chip provided in Embodiment 4 of the present application;

FIGS. 8-10 show the schematic diagram of light traveling from an optically thinner medium to an optically denser medium, as provided in Embodiment 4 of the present application;

FIGS. 8-11 depict the simulation schematic of light propagation provided in Embodiment 4 of the present application;

FIGS. 8-12 present the simulation schematic of light reflection angles provided in Embodiment 4 of the present application;

FIGS. 8-13a illustrate the schematic of an LED device product with a light emission angle of 90° in the related art;

FIGS. 8-13b illustrate the schematic of an LED device product with a light emission angle of 90° in the related art;

FIGS. 8-13c illustrate the schematic of an LED device product with a light emission angle of 90° in the related art.

### DESCRIPTION OF EMBODIMENTS

To facilitate understanding of the present application, a more comprehensive description will be provided below with reference to the accompanying drawings. Preferred embodiments of the present application are given in the drawings. However, the present application can be implemented in many different forms and is not limited to the embodiments described herein. On the contrary, these embodiments are provided to make the disclosure of the present application more thorough and comprehensive.

Unless otherwise defined, all technical and scientific terms used herein have the same meanings as commonly understood by those skilled in the technical field of the present application. The terminology used in the description of the present application is intended only to describe specific embodiments and is not intended to limit the application.

It should be noted that the terms “first,” “second,” etc., used in the specification and claims of the present application and the above drawings are for distinguishing similar objects and do not necessarily imply a specific order or sequence. It should be understood that such data may be interchanged where appropriate to enable the embodiments of the present application described herein. Furthermore, the terms “include” and “have” and any variations thereof are intended to cover non-exclusive inclusion. For example, a process, method, system, product, or device that includes a series of steps or units is not necessarily limited to those steps or units explicitly listed but may include other steps or units inherent to such processes, methods, products, or devices that are not explicitly listed.

In the present application, the orientation or positional relationships indicated by terms such as “upper,” “lower,” “inner,” “middle,” “outer,” “front,” and “rear” are based on the orientation or positional relationships shown in the accompanying drawings. These terms are primarily used to better describe the present application and its embodiments and are not intended to limit the devices, components, or parts to a specific orientation or to be constructed and operated in a specific orientation. Moreover, some of the above terms may also be used to indicate other meanings besides orientation or positional relationships. For example, the term “upper” may, in certain contexts, denote a dependency or connection relationship. Those of ordinary skill in the art can understand the specific meanings of these terms in the present application based on the context. Additionally, the terms “arranged,” “connected,” and “fixed” should be interpreted broadly. For instance, “connected” may refer to a fixed connection, a detachable connection, or an integral structure; it may be a mechanical connection or an electrical connection; it may be a direct connection, an indirect connection through an intermediary, or an internal communication between two devices, components, or parts. Those of ordinary skill in the art can understand the specific meanings of the above terms in the present application based on the context.

It should be noted that, in the absence of conflict, the embodiments in the present application and the features in the embodiments can be combined with each other. The application will be described in detail below with reference to the accompanying drawings and embodiments.

The present application provides an LED device, which can be applied to various lighting fields, such as household lighting, office lighting, plant lighting, and medical lighting; it can also be applied to optical signal fields, such as any field that uses light as a transmission signal, where the light may be visible or invisible. The LED device in this embodiment includes a light-emitting unit, which may include at least one LED chip. The LED device further includes an encapsulation layer disposed on the light-emitting units to cover the light-emitting units, through which the light emitted by the light-emitting unit exits; covering the light-emitting unit with the encapsulation layer provides protection, thereby improving reliability. The light-emitting chips included in the light-emitting unit may include, but is not limited to, micron-level LED chips (e.g., Mini LED chips or Micro LED chips), such as micron-level flip-chip LED chips. Of course, all or part of them may also be replaced with micron-level wire-bonded or vertical LED chips. In terms of size, they can also be replaced with LED chips larger than Mini LED chips as needed. The light-emitting color of the light-emitting chip can be flexibly configured according to specific application requirements.

Evidently, the LED device provided in the present application offers better reliability and a wide range of applicable scenarios. For ease of understanding, illustrative explanations are provided below in conjunction with the following embodiments.

### Embodiment 1

In related art, the concept of full-spectrum is a branch of LED lighting with extremely long-term prospects. The idea is that the closer the emission spectrum is to natural light, the better its health lighting effect on the human body. Currently, the mainstream LED lighting products on the market primarily rely on blue light exciting phosphors. Common full-spectrum LEDs generally pursue parameters such as the color rendering index Ra and R9 in the CIE (English: International Commission on Illumination, French: Commission Internationale de l'Eclairage, abbreviated as CIE in French) color evaluation system, while neglecting the continuity of the spectrum and its similarity to natural light spectra. This results in existing full-spectrum LED devices having poor spectral continuity, high blue light peaks, and low similarity to natural light.

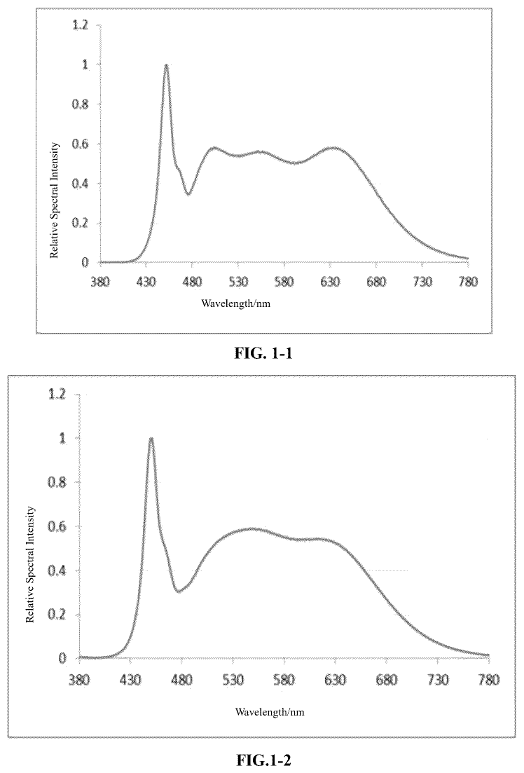

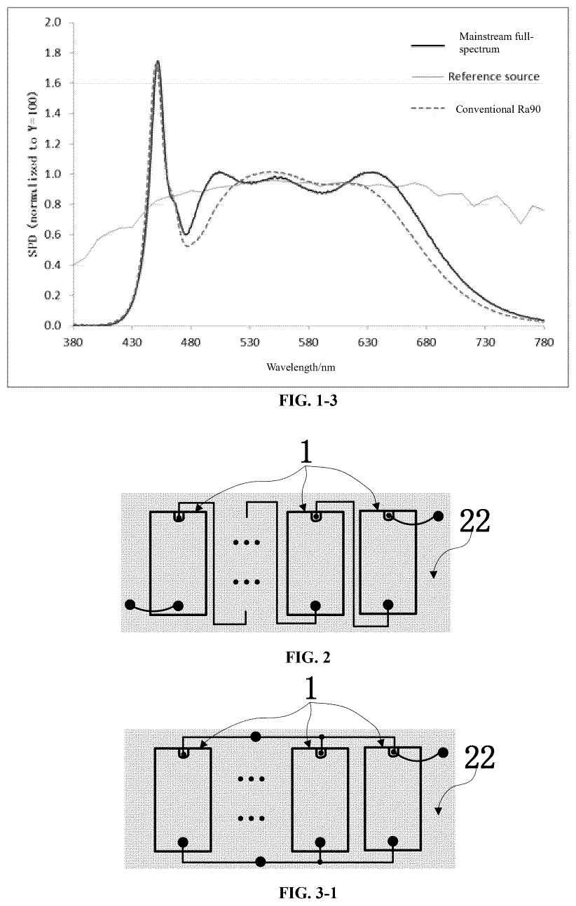

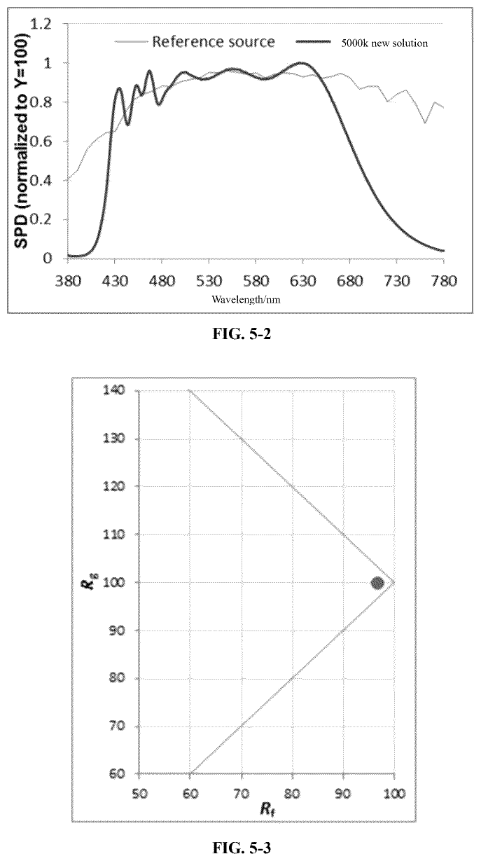

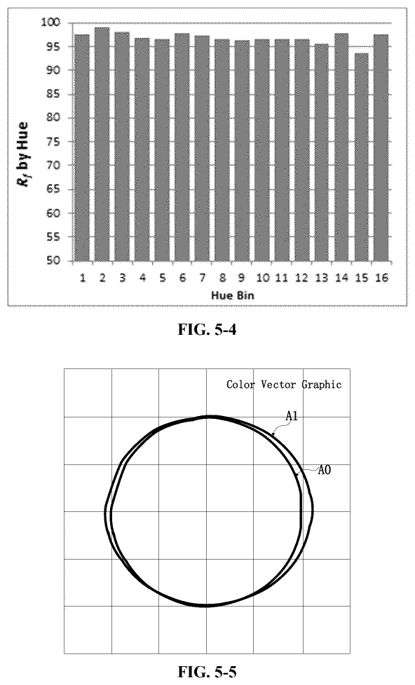

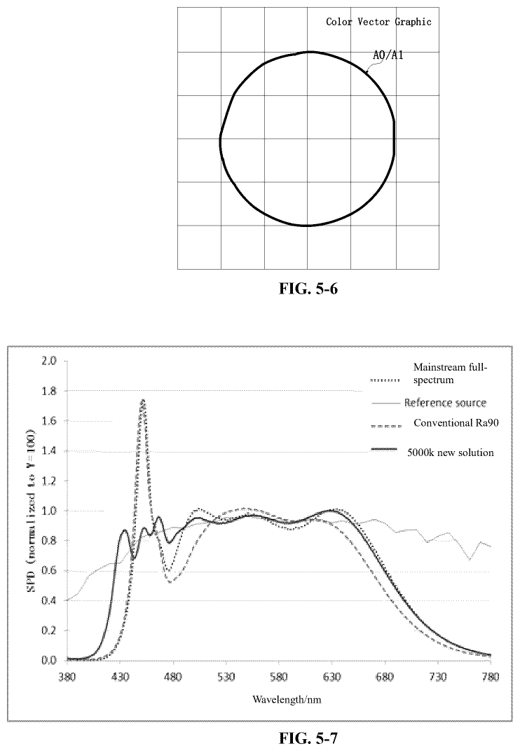

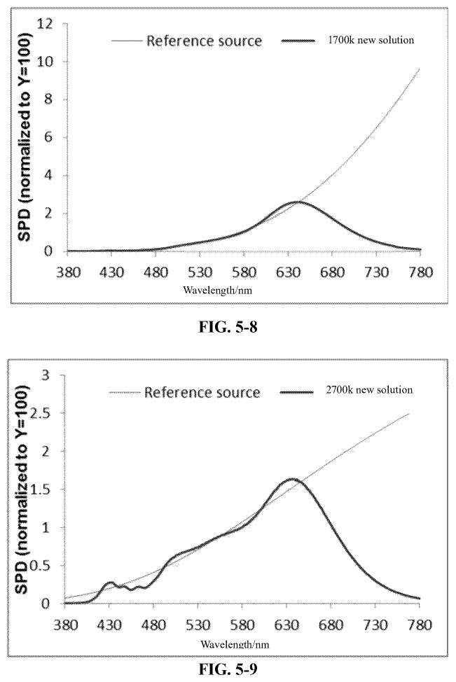

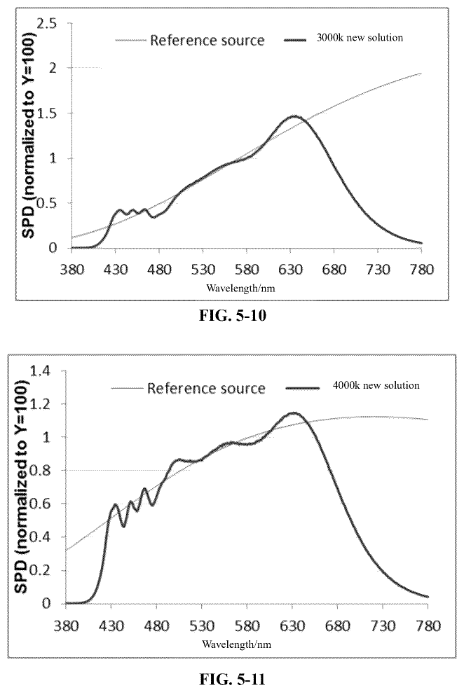

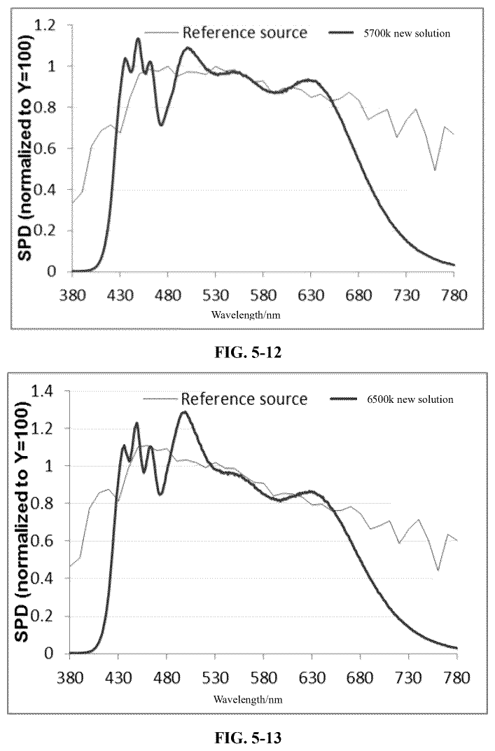

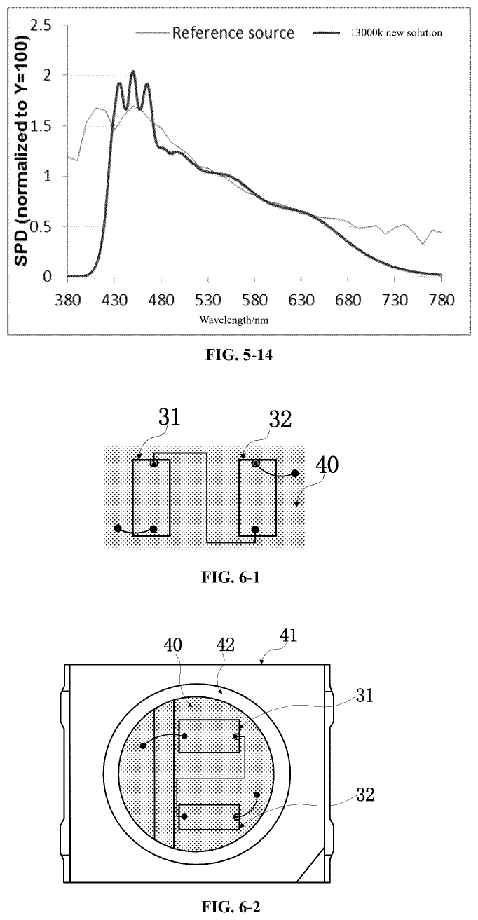

To facilitate understanding, the following provides an illustrative explanation based on the process by which the inventors identified this issue during research and development. Here, 5000K is taken as a typical color temperature to illustrate the problem. The spectrum of current full-spectrum LED devices on the market (hereinafter referred to as “mainstream light sources”) is shown in FIG. 1-1, while the spectrum of conventional Ra90 LED devices (hereinafter referred to as “conventional Ra90”) is shown in FIG. 1-2. The typical color rendering index parameters of both are listed in Table 1 below. In FIGS. 1-1 and 1-2, the horizontal axis represents wavelength, and the vertical axis represents relative spectral intensity. Here, the relative spectral intensity refers to a spectral diagram generated by normalizing the spectrum with the highest peak of spectral intensity set as 1. In this embodiment, FIG. 5-1 is also generated based on the same principle, and further details will not be repeated hereafter.

TABLE 1

| Color Rendering | Mainstream | Conventional |
|---|---|---|
| Index Parameter | Light Source | Ra90 |
| Ra | 98.6 | 91.7 |
| R1 | 98.79 | 91.12 |
| R2 | 99.33 | 93.23 |
| R3 | 99.5 | 93.89 |
| R4 | 98.83 | 91.32 |
| R5 | 98.63 | 89.77 |
| R6 | 97.86 | 89.24 |
| R7 | 97.8 | 96.47 |
| R8 | 97.48 | 88.24 |
| R9 | 97.06 | 65.89 |
| R10 | 98.26 | 83.12 |
| R11 | 97.39 | 90.42 |
| R12 | 81.11 | 63.93 |
| R13 | 98.76 | 91.55 |
| R14 | 99.36 | 96.55 |
| R15 | 96.93 | 89.03 |

Refer to the Ra and R9 parameters in Table 1. Compared to conventional Ra90 products, mainstream light sources on the market have indeed shown improvement. For better understanding, Rf (Fidelity, or gamut value) and Rg (Saturation) evaluation system of the IES (Illuminating Engineering Society of North America) TM-30-15 standard is introduced below. The spectral diagrams shown in FIGS. 1-1 and 1-2 are incorporated into the same SPD (Spectral Power Distribution) diagram for comparative analysis, as illustrated in FIG. 1-3. Here, the Reference source represents natural light, and the diagram is generated by normalizing the energy of the compared spectrum (i.e., the Reference source in the diagram) to 1 as the baseline, displaying both the compared and reference spectra. In this embodiment, FIGS. 5-2, 5-7 to 5-14 are also generated using the same principle, which will not be reiterated later. The hue parameters measured under the TM-30-15 standard are listed in Table 2.

TABLE 2

| | Mainstream | Conventional |
|---|---|---|
| Tone parameters | light sources | Ra90 |
| Rg | 99 | 98 |
| Rf | 92 | 89 |
| 1 | 94.1 | 88.9 |
| 2 | 97.3 | 93.1 |
| 3 | 93.6 | 90.3 |
| 4 | 90.1 | 91.4 |
| 5 | 89.1 | 91.4 |
| 6 | 94.7 | 95.5 |
| 7 | 92.3 | 93.9 |
| 8 | 90.4 | 90.2 |
| 9 | 90.3 | 87.9 |
| 10 | 90.3 | 81.9 |
| 11 | 89.3 | 80.3 |
| 12 | 93.2 | 88.1 |
| 13 | 92.8 | 91.4 |
| 14 | 93.9 | 92.2 |
| 15 | 84.7 | 81.4 |
| 16 | 94.4 | 89 |

In the TM-30-15 standard, Rf is used to characterize the degree of similarity between standard colors illuminated by the test light source and those under the reference light source, with values ranging from 0 to 100. A higher value indicates better color fidelity. An Rf of 100 represents the maximum value, indicating no color difference compared to natural light and achieving realistic color effects; an Rf of 0 is the minimum value, representing the largest color difference from natural light and distorted color effects. Rg is used to characterize the saturation level of standard colors under the test light source compared to the reference light source, with an index of 100 representing optimal saturation. Rg equal to 100 indicates that the light source's saturation matches natural light, providing moderate color saturation; Rg greater than 100 indicates oversaturation; Rg less than 100 indicates insufficient color saturation.

From the spectral comparison in FIGS. 1-3, it can be observed that the mainstream light sources currently on the market exhibit poor spectral continuity and similarity to natural light, along with higher blue light peaks, when compared to the reference natural light spectrum.

To facilitate understanding of the continuity issue, the concept of ASD (Average Spectral Difference) is introduced here. ASD represents the ratio of the spectral difference area between the tested light source and the standard light source to the spectral area of the standard light source. It serves as an indicator of spectral continuity, where smaller values are better, with 0 being the minimum. The ASD value is calculated using the following formula (1):

$$ASD = {\int }_{λ 1}^{λ 2} \vert A ( λ ) - S ( λ ) \vert / S ( λ ) d λ \qquad ( 1 )$$

where A(λ) is the target spectrum, and S(λ) is the natural light spectrum. Let λ=400 nm,
λ2=700 nm, the ASD values calculated according to the above formula (1) are listed in Table 3.

TABLE 3

| | Mainstream | Conventional |
|---|---|---|
| Parameter | light source | Ra90 |
| ASD | 23.62% | 28.01% |

As can be seen from Table 3, the ASD values of mainstream light sources on the market have decreased compared to conventional Ra90, but there remains a significant gap when compared to natural light. That is, the similarity (or fitting degree) to the target spectrum of natural light is still insufficient.

It is evident that existing full-spectrum LED devices exhibit poor spectral continuity, high blue light peaks, and low similarity to natural light. To address these technical issues, this embodiment provides an LED device with low blue light and full-spectrum characteristics.

Research shows that, as seen in the spectral comparison of FIGS. 1-3, the blue light band from 400 nm to 500 nm is the band where spectral continuity can be most effectively improved. Therefore, this embodiment introduces a novel design for the blue light band from 400 nm to 500 nm for the LED device, significantly reducing the blue light peak. This effectively resolves the issue of poor continuity in the blue light region, bringing it as close as possible to natural light, thereby achieving better continuity, enhanced eye protection, and superior color performance.

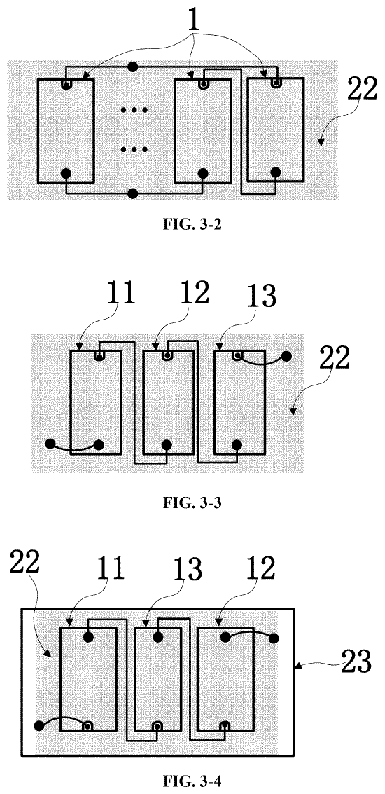

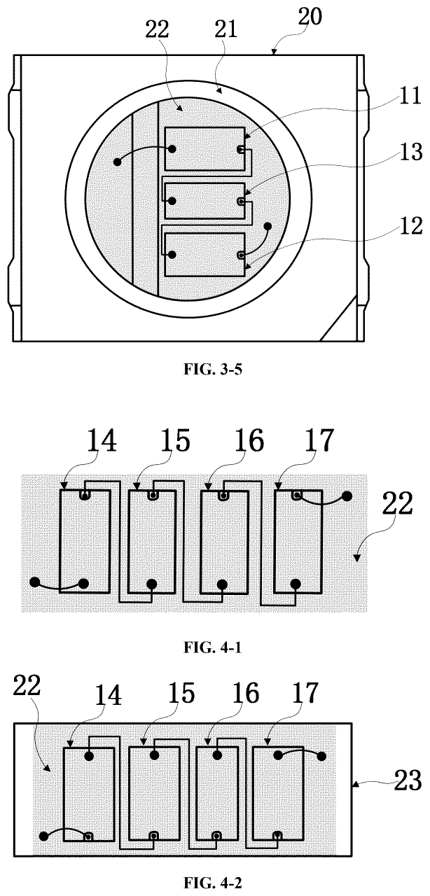

Referring to FIG. 2, the low-blue-light full-spectrum LED device provided in this embodiment includes a first light-emitting unit, which includes at least three sets of blue light LED chip units 1. The blue light peak wavelengths of these units range from 415 nm to 470 nm. In this embodiment, the at least three sets of blue light LED chip units 1 are connected in series, as shown in FIG. 2. Alternatively, they can be connected in parallel (FIG. 3-1) or in a series-parallel combination (FIG. 3-2), with the specific electrical connection tailored to application needs. In this embodiment, based on the principle of balancing blue light energy distribution, the blue light peak wavelengths of the at least three sets of blue LED chip units 1 are progressively increased within the range of 415 nm to 470 nm, thereby achieving a balanced distribution of blue light energy.

As shown in FIGS. 2 to 3-2, the encapsulation layer in this embodiment includes a first phosphor gel 22 that covers at least three sets of blue light LED chip units 1. The first phosphor gel 22 includes a first encapsulant and a first full-spectrum phosphor mixed within the first encapsulant. In this embodiment, the first full-spectrum phosphor includes first cyan phosphor, first green phosphor, first yellow phosphor, and first red phosphor. This requires fewer types of phosphors, simplifying production and reducing costs. Of course, it should be understood that in some applications, at least one of the first cyan phosphor, first green phosphor, first yellow phosphor, or first red phosphor can be equivalently replaced with corresponding QD (Quantum Dot).

In this embodiment, the spectral coupling between the at least three sets of blue light LED chip units 1 and the first full-spectrum phosphor in the first phosphor gel 22 reduces the blue light peak wavelength in the LED device's spectrum, improves the spectral continuity of the LED device, and enhances its resemblance to natural light, bringing it closer to natural light as much as possible and achieving better color effects.

In this embodiment, the blue LED dies can be distinguished by size as Mini LED chips, Micro LED chips, or conventional large-sized LED chips. Alternatively, some may be one type among Mini LED chips, Micro LED chips, and conventional large-sized LED chips, while others may be at least one of the remaining two types. In terms of electrode distribution, the blue LED dies in this embodiment can all be either wire-bonded LED chips, flip-chip LED chips, or vertical LED chips, or some may be one type among wire-bonded LED chips, flip-chip LED chips, and vertical LED chips, while others may be at least one of the remaining two types. The specific configuration can be flexibly adjusted based on application requirements, offering good versatility.

For the blue LED dies, the wavelength of the blue light is directly related to the In component content in the dies. The In component can be controlled by regulating the In amount introduced and growth temperature during the epitaxial growth of GaN/InGaN quantum wells within the epitaxial layer of the blue LED dies, thereby regulating the In component. For example, a higher In content results in a longer wavelength of the blue LED dies, while a higher temperature increases In volatilization, reducing In content and shortening the wavelength of the blue LED dies. Therefore, in this embodiment, the blue light peak wavelength of the blue LED dies can be set by controlling the In component in the blue LED dies.

Since the excitation efficiency of the blue LED die on the phosphor decreases with increasing wavelength, and different phosphors have fixed excitation efficiency curves, this embodiment achieves a full-spectrum LED device with low blue light, spectral continuity, and high similarity to natural light by designing the spectral energy and wavelength combination of the blue LED die. For ease of understanding, the following description in this embodiment uses several specific examples of blue light LED chip unit configurations.

### Example 1

In this example, as shown in FIG. 3-3, the blue light LED chip unit of the LED device includes a first blue light LED chip unit 11, a second blue light LED chip unit 12, and a third blue light LED chip unit 13 connected in series, as well as a first phosphor gel 22 covering these three blue light LED chip units (it should be understood that FIG. 3-3 may also adopt specific electrical connection methods such as the parallel connection shown in FIG. 3-1 or the series-parallel combination shown in FIG. 3-2). The blue light peak wavelengths of the first blue light LED chip unit 11, the second blue light LED chip unit 12, and the third blue light LED chip unit 13 increase sequentially within the range of 415 nm to 470 nm. Based on the principle of balancing blue light energy distribution, this example specifically sets the blue light peak wavelengths of the first blue light LED chip unit 11, the second blue light LED chip unit 12, and the third blue light LED chip unit 13 to increase sequentially within the range of 430 nm to 465 nm, where: the blue light peak wavelength of the first blue light LED chip unit 11 is set to 430 nm to 440 nm, the blue light peak wavelength of the second blue light LED chip unit 12 is set to 445 nm to 455 nm, and the blue light peak wavelength of the third blue light LED chip unit 13 is set to 455 nm to 465 nm.

In this example, to match the above blue light distribution, the first full-spectrum phosphor is configured to include the first cyan phosphor, first green phosphor, first yellow phosphor, and first red phosphor. In some application scenarios of this example, the first full-spectrum phosphor can be composed of the first cyan phosphor, first green phosphor, first yellow phosphor, and first red phosphor. Specifically, the first cyan phosphor is set to have an emission peak wavelength of 490 nm to 510 nm under blue light excitation, the first green phosphor has an emission peak wavelength of 520 nm to 540 nm under blue light excitation, the first yellow phosphor has an emission peak wavelength of 570 nm to 590 nm under blue light excitation, and the first red phosphor has an emission peak wavelength of 650 nm to 660 nm under blue light excitation.

To further enhance the spectral continuity of the LED device, the radiant flux in this example, also referred to as radiant power, denotes the radiant energy passing through a given cross-section per unit time, representing the power emitted, transmitted, or received in the form of radiation, with its absolute unit being mW. In this example, based on the radiant flux of the second blue light LED chip unit 12 being 100%, the radiant flux of the first blue light LED chip unit 11 ranges from 80% to 120%, while that of the third blue light LED chip unit 13 ranges from 60% to 100%. The combined blue light spectrum obtained from these three units is illustrated in FIG. 5-1. In this example, the size of the blue LED die in the third blue light LED chip unit 13 can be smaller than those in the first and second blue light LED chip units 11 and 12. This arrangement of varying die sizes not only facilitates flexible die layout but also reduces costs. Additionally, positioning the third blue light LED chip unit 13 between the first and second blue light LED chip units 11 and 12 enhances light mixing among the three blue light LED chip units, further improving the light output effect.

In this example, to further enhance the spectral continuity of the LED device, the full width at half maximum of the second blue light LED chip unit 12 and the third blue light LED chip unit 13 can also be set to 10 nm to 20 nm, while the full width at half maximum of the first blue light LED chip unit 11 is set to 15 nm to 25 nm. In this example, the full width at half maximum characterizes the magnitude of energy band transitions during energy transitions the more energy bands available for transition, the larger the full width at half maximum. Correspondingly, the slower the growth rate of the die, the smaller the full width at half maximum; the faster the growth rate, the larger the full width at half maximum. Therefore, the full width at half maximum of the blue LED die can be flexibly adjusted by controlling the growth rate of the die. By coordinating the wavelength bands and full widths at half maximum of the three sets of blue LED dies in this example, an LED device with a blue light spectrum portion distributed according to the desired radiant flux ratio can be achieved.

Correspondingly, in this example, to further improve the spectral continuity of the LED device, the full width at half maximum of the first cyan phosphor in the first full-spectrum phosphor under blue light excitation can be set to 30 nm to 40 nm, the full width at half maximum of the first green phosphor under blue light excitation to 95 nm to 115 nm, the full width at half maximum of the first yellow phosphor under blue light excitation to 40 nm to 70 nm, and the full width at half maximum of the first red phosphor under blue light excitation to 80 nm to 100 nm.

In this example, through the combination of the aforementioned blue light chipset and the first phosphor gel, a light source with an extremely wide effective synthesized color temperature range can be obtained. For ease of understanding, two specific application scenarios are described below as examples.

In one application scenario, as shown in FIGS. 3-5, the LED device further includes a first LED lead frame 20. The first LED lead frame 20 includes a reflector cup 21 (also referred to as a reflective cavity or accommodating cavity), and each blue light LED chip unit is positioned within the reflector cup 21. As illustrated in FIGS. 3-5, in this scenario, the first blue light LED chip unit 11, the third blue light LED chip unit 13, and the second blue light LED chip unit 12 are all placed within the reflector cup 21 and connected in series (alternatively, parallel connection as shown in FIG. 3-1 or a combination of series-parallel connection as shown in FIG. 3-2 may be adopted for specific electrical connections). The third blue light LED chip unit 13 is located between the first blue light LED chip unit 11 and the second blue light LED chip unit 12. In this scenario, the first blue light LED chip unit 11, the third blue light LED chip unit 13, and the second blue light LED chip unit 12 may each include only one blue LED die. However, it should be understood that, based on actual requirements, at least one of the first blue light LED chip unit 11, the third blue light LED chip unit 13, or the second blue light LED chip unit 12 may include two or more blue LED dies. When a blue light LED chip unit contains two or more blue LED dies, these dies can be connected in series, parallel, or a combination thereof. In this scenario, the structure of the first LED lead frame 20 and the specific shape or dimensions of the reflector cup 21 are not limited. The LED device shown in FIG. 3-5 in this scenario is a surface-mount LED device. When the color temperature of the LED device in FIG. 3-5 is 1700K, 2700K, or 3000K, the mass ratio of the first full-spectrum phosphor to the first encapsulant is 1:1 to 2:1. For a color temperature of 4000K, the mass ratio ranges from 1:2 to 1:1. For color temperatures of 5000K, 5700K, or 6500K, the mass ratio is 1:3 to 1:1. At a color temperature of 13000K, the mass ratio is 1:5 to 1:2, as shown in Table 4 below. Under these color temperatures, an example ratio of the first cyan phosphor, first green phosphor, first yellow phosphor, and first red phosphor in the first full-spectrum phosphor is shown but not limited to Table 4 below.

TABLE 4

| | Color Temperature | | | | | | | |
|---|---|---|---|---|---|---|---|---|
| Category | 1700K | 2700K | 3000K | 4000K | 5000K | 5700K | 6500K | 13000K |
| Mass ratio of the | 1:1 to | 1:1 to | 1:1 to | 1:2 to | 1:3 to | 1:3 to | 1:3 to | 1:5 to |
| first full-spectrum | 2:1 | 2:1 | 2:1 | 1:1 | 1:1 | 1:1 | 1:1 | 1:2 |
| phosphor to the first | | | | | | | | |
| encapsulant | | | | | | | | |
| Proportion of the | 0% to | 0% to | 0% to | 0% to | 5% to | 5% to | 10% to | 5% to |
| first cyan phosphor | 5% | 10% | 10% | 10% | 15% | 15% | 20% | 15% |
| Proportion of the | 75% to | 75% to | 75% to | 75% to | 75% to | 80%- | 70% to | 80% to |
| first green phosphor | 85% | 90% | 90% | 95% | 85% | 90% | 80% | 90% |
| Proportion of the | 0% to | 0% to | 0% to | 0% to | 0% to | 0% to | 0% to | 0% to |
| first yellow phosphor | 5% | 5% | 5% | 5% | 5% | 5% | 5% | 5% |
| Proportion of the | 10% to | 5% to | 10% to | 5% to | 5% to | 5% to | 5% to | 5% to |
| first red phosphor | 20% | 15% | 20% | 15% | 15% | 15% | 15% | 15% |

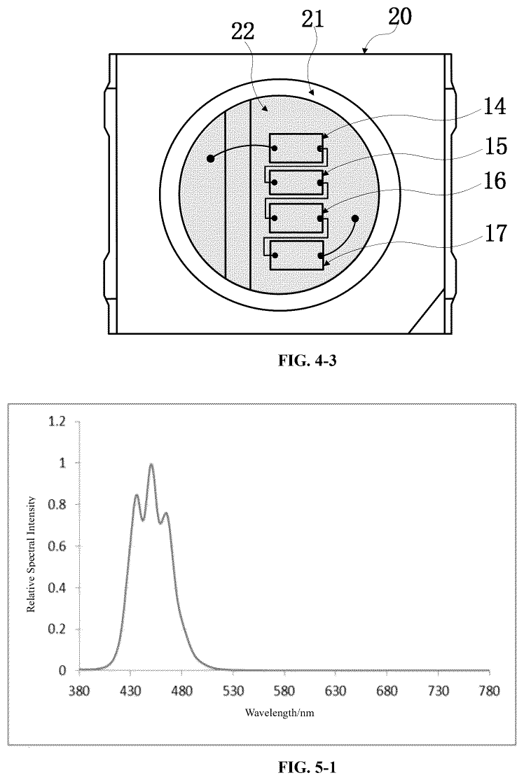

The LED device shown in FIG. 3-5 offers advantages such as low blue light, spectral continuity, and high similarity to natural light. For ease of understanding, its optical performance at a color temperature of 5000K is used as an example for illustration. Under the TM-30-15 standard, the evaluation of the LED device in FIG. 3-5 (hereinafter referred to as the “new light source”) at a 5000K color temperature is shown in FIGS. 5-2 to 5-7. Among them, FIG. 5-2 displays the spectral power distribution, while FIG. 5-7 adds the spectral comparison from FIG. 5-2 to the baseline of FIG. 1-3. The “Reference source” represents natural light, and the hue parameters measured under the TM-30-15 standard are listed in Table 5. FIG. 5-3 shows a Rf-Rg schematic, where the black dots represent the reference light source (i.e., natural light), and FIG. 5-4 is the Rf hue diagram. As seen in FIG. 5-4, the Rf values of the new light source for each standard color (indicated by the horizontal axis) are significantly greater than 90, mostly ranging between 95 and 100. By correlating the Rf values in FIGS. 5-3 and 5-4 with the Rg, it is evident that the Rg values also predominantly fall between 95 and 100. Furthermore, according to the test results in Table 5, when Rf is 97.9, the Rg value can reach 100. This clearly demonstrates that the spectral continuity of the LED device in FIG. 3-5 and its similarity to natural light have significantly improved, the blue light peak has drastically decreased, and both Rf and Rg have seen substantial enhancements.

TABLE 5

| Tone | Mainstream | Conventional | New light |
|---|---|---|---|
| parameters | light sources | Ra90 | sources |
| Rg | 99 | 98 | 100 |
| Rf | 92 | 89 | 97.9 |
| 1 | 94.1 | 88.9 | 98 |
| 2 | 97.3 | 93.1 | 99 |
| 3 | 93.6 | 90.3 | 98 |
| 4 | 90.1 | 91.4 | 97 |
| 5 | 89.1 | 91.4 | 97 |
| 6 | 94.7 | 95.5 | 98 |
| 7 | 92.3 | 93.9 | 97 |
| 8 | 90.4 | 90.2 | 97 |
| 9 | 90.3 | 87.9 | 96 |
| 10 | 90.3 | 81.9 | 97 |
| 11 | 89.3 | 80.3 | 97 |
| 12 | 93.2 | 88.1 | 97 |
| 13 | 92.8 | 91.4 | 96 |
| 14 | 93.9 | 92.2 | 98 |
| 15 | 84.7 | 81.4 | 94 |
| 16 | 94.4 | 89 | 98 |

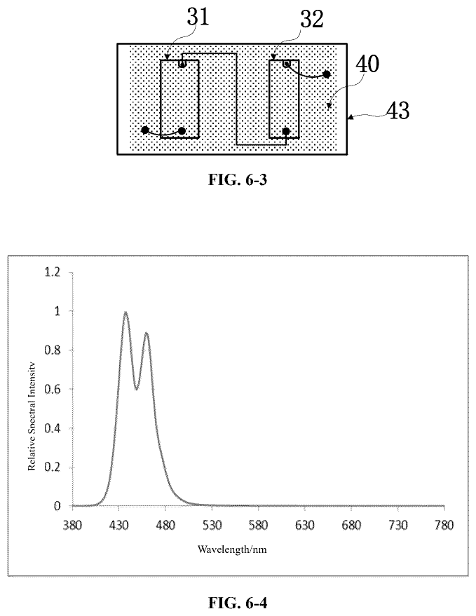

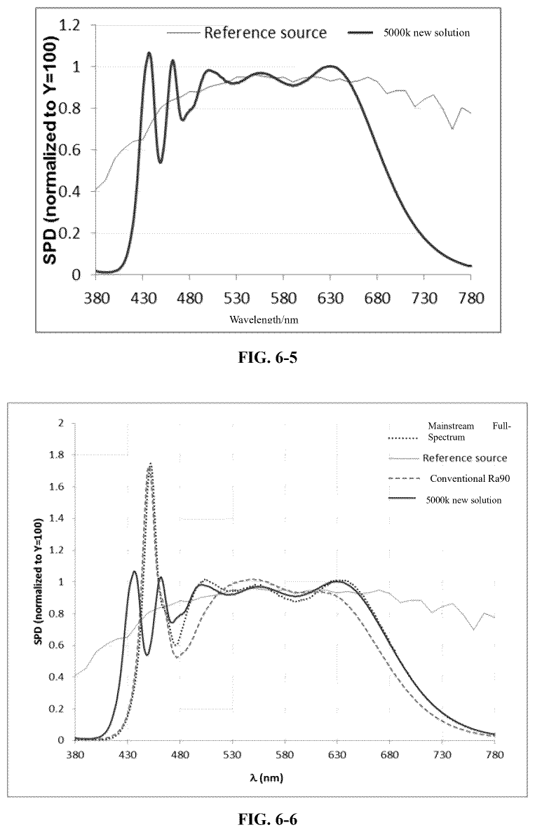

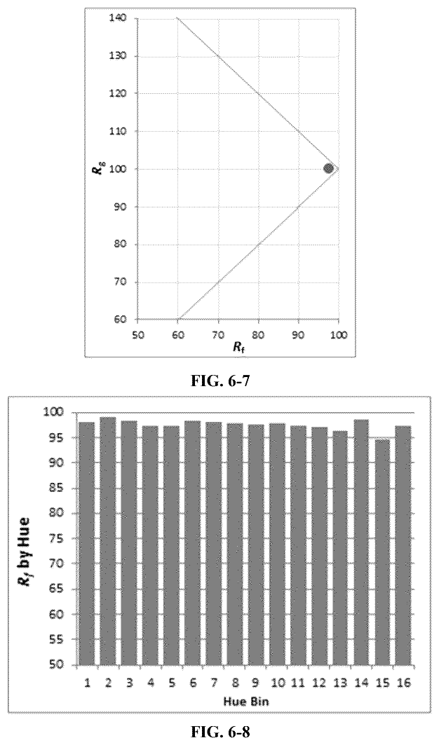

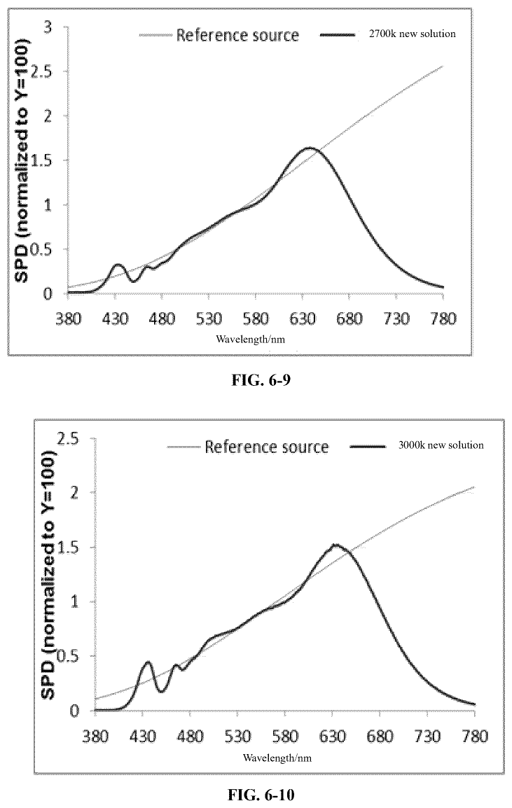

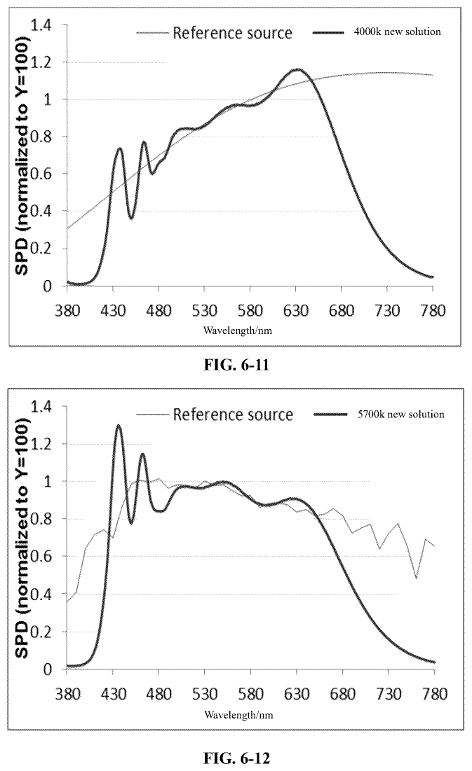

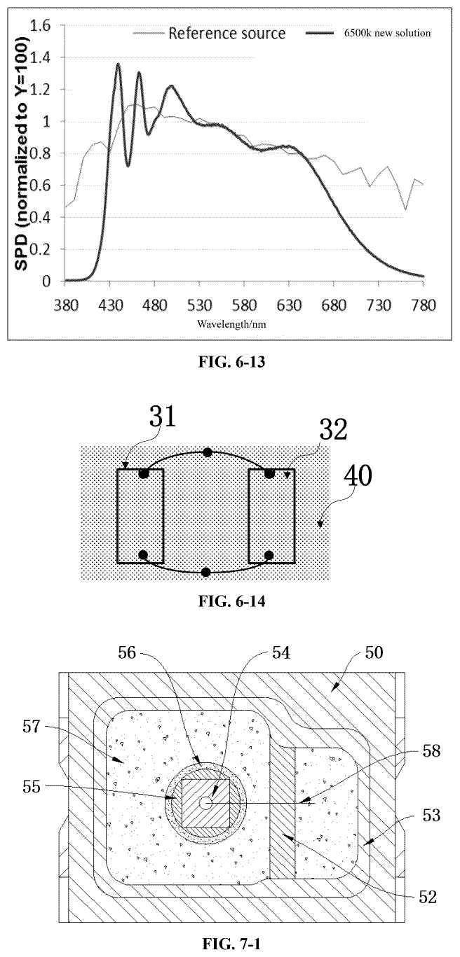

FIG. 5-5 shows the existing chromaticity vector diagram, where the A0 circle represents the reference light source (natural light), composed of 16 color classifications of the reference light source, and the A1 circle represents the test light source. Any red line inside the A0 circle indicates that these colors of the test light source appear duller compared to the reference light source, while any line outside the A0 circle indicates that these colors of the test light source are oversaturated relative to the reference light source. When the A0 and A1 circles perfectly overlap, it means these colors of the test light source and the reference light source are identical, with no difference in color rendering between the two light sources. FIG. 5-6 displays the chromaticity vector diagram of the LED device from FIG. 3-5, where the A0 and A1 circles perfectly overlap, indicating that the light emitted by the LED device in FIG. 3-5 has virtually no difference in color rendering compared to the reference light source (natural light). In other words, the light emitted by the LED device can closely approximate natural light, enabling the LED device to achieve better continuity effects, significantly improving its similarity to natural light, and delivering superior eye protection and color performance. The ASD values calculated using the aforementioned formula (1) are shown in Table 6, which further validates this from another perspective.

TABLE 6

| | Mainstream | Conventional | New light |
|---|---|---|---|
| Parameter | light source | Ra90 | source |
| ASD | 23.62% | 28.01% | 14.13% |

In another application scenario, as shown in FIG. 3-4, compared to the LED device illustrated in FIG. 3-5, the main difference lies in replacing the first LED lead frame 20 in FIG. 3-5 with the first base plate 23. In this scenario, there are no restrictions on the structure of the first base plate 23, whether it is flexible or rigid, or its specific shape and dimensions. The LED device depicted in FIG. 3-4 in this scenario is a COB (Chip On Board) LED device. Here, when the color temperature of the LED device in FIG. 3-4 is 1700K, 2700K, or 3000K, the mass ratio of the first full-spectrum phosphor to the first encapsulant ranges from 1:2 to 1:1. When the color temperature is 4000K, the mass ratio of the first full-spectrum phosphor to the first encapsulant is 1:3 to 1:1. For color temperatures of 5000K, 5700K, or 6500K, the mass ratio is 1:4 to 1:1, and for a color temperature of 13000K, the mass ratio of the first full-spectrum phosphor to the first encapsulant is 1:5 to 1:2. At each of these color temperatures, an example proportion of the first cyan phosphor, first green phosphor, first yellow phosphor, and first red phosphor in the first full-spectrum phosphor is shown, but not limited to, Table 7 below.

TABLE 7

| | Color Temperature | | | | | | | |
|---|---|---|---|---|---|---|---|---|
| Category | 1700K | 2700K | 3000K | 4000K | 5000K | 5700K | 6500K | 13000K |
| Mass ratio of the | 1:2 to | 1:2 to | 1:2 to | 1:3 to | 1:4 to | 1:4 to | 1:4 to | 1:5 to |
| first full-spectrum | 1:1 | 1:1 | 1:1 | 1:1 | 1:1 | 1:1 | 1:1 | 1:2 |
| phosphor to the first | | | | | | | | |
| encapsulant | | | | | | | | |
| Proportion of the | 0% to | 0% to | 0% to | 0% to | 5% to | 5% to | 10% to | 5% to |
| first cyan phosphor | 5% | 10% | 10% | 10% | 15% | 15% | 20% | 15% |
| Proportion of the | 75% to | 75% to | 75% to | 75% to | 75% to | 80%- | 70% to | 80% to |
| first green phosphor | 85% | 90% | 90% | 95% | 85% | 90% | 80% | 90% |
| Proportion of the | 0% to | 0% to | 0% to | 0% to | 0% to | 0% to | 0% to | 0% to |
| first yellow phosphor | 5% | 5% | 5% | 5% | 5% | 5% | 5% | 5% |
| Proportion of the | 10% to | 5% to | 10% to | 5% to | 5% to | 5% to | 5% to | 5% to |
| first red phosphor | 20% | 15% | 20% | 15% | 15% | 15% | 15% | 15% |

The LED device shown in FIG. 3-4 also boasts advantages such as low blue light, spectral continuity, and high similarity to natural light. Testing reveals that the optical performance of the LED device in FIG. 3-4 and the one in FIG. 3-5 is essentially identical at a color temperature of 5000K. Additionally, their spectral power distribution diagrams at 1700K, 2700K, 3000K, 4000K, 5700K, 6500K, and 13000K can be found in FIGS. 5-8 to 5-14, respectively (refer to the curves labeled as the new solution in the figures).

In other application scenarios of this example, based on the principle of balancing blue light energy distribution, the blue light peak wavelengths of the first blue light LED chip unit 11, the second blue light LED chip unit 12, and the third blue light LED chip unit 13 in FIG. 3-4 or FIG. 3-5 can be specifically set to increase sequentially within the range of 415 nm to 470 nm.

For example, the blue light peak wavelength of the first blue light LED chip unit 11 can be specifically set to 415 nm to 430 nm, the blue light peak wavelength of the second blue light LED chip unit 12 to 440 nm to 450 nm, and the blue light peak wavelength of the third blue light LED chip unit 13 to 450 nm to 465 nm. The full width at half maximum range of each group of blue LED chip units can be appropriately adjusted or remain unchanged, while the first full-spectrum phosphor remains unchanged or is adjusted accordingly. Alternatively, the blue light peak wavelength of the first blue light LED chip unit 11 can be set to 420 nm to 435 nm, the second blue light LED chip unit 12 to 436 nm to 450 nm, and the third blue light LED chip unit 13 to 455 nm to 460 nm. The full width at half maximum range of each group of blue LED chip units can be appropriately adjusted or remain unchanged, and the first full-spectrum phosphor remains unchanged or is adjusted accordingly. Or, the blue light peak wavelength of the first blue light LED chip unit 11 can be set to 400 nm to 435 nm, the second blue light LED chip unit 12 to 440 nm to 450 nm, and the third blue light LED chip unit 13 to 450 nm to 460 nm. The full width at half maximum range of each group of blue LED chip units can be appropriately adjusted or remain unchanged, and the first full-spectrum phosphor remains unchanged or is adjusted accordingly. Testing has shown that the light output effect of the LED device after the above adjustments is similar to that of the LED device shown in FIGS. 3-5, meaning it improves spectral continuity and similarity to natural light while also reducing the blue light peak.

### Example 2

In this example, referring to FIG. 4-1, the blue light LED chip unit of the LED device includes electrically connected fourth blue light LED chip unit 14, fifth blue light LED chip unit 15, sixth blue light LED chip unit 16, and seventh blue light LED chip unit 17. The specific connection method for these four sets of blue light LED chip units can be series, parallel, or a combination of series and parallel. Moreover, the blue light peak wavelengths of these four sets of blue LED dies increase sequentially within the range of 415 nm to 470 nm. For instance, based on the principle of balancing blue light energy distribution, the blue light peak wavelength of the fourth blue light LED chip unit 14 can be set to 415 nm to 425 nm, the blue light peak wavelength of the fifth blue light LED chip unit 15 is set to 430 nm to 440 nm, the blue light peak wavelength of the sixth blue light LED chip unit 16 is set to 445 nm to 455 nm, and the blue light peak wavelength of the seventh blue light LED chip unit 17 is set to 460 nm to 470 nm.

In this example, to match the above blue light distribution, the first full-spectrum phosphor is configured to include first cyan phosphor, first green phosphor, first yellow phosphor, and first red phosphor. In some application scenarios of this example, the first full-spectrum phosphor can be composed of first cyan phosphor, first green phosphor, first yellow phosphor, and first red phosphor. Specifically, the first cyan phosphor is set to have an emission peak wavelength of 490 nm to 510 nm under blue light excitation, the first green phosphor 520 nm to 540 nm, the first yellow phosphor 570 nm to 590 nm, and the first red phosphor 650 nm to 660 nm under blue light excitation.

To further enhance the spectral continuity of the LED device in this example, in some application scenarios of this example, the radiant flux of the fourth blue LED die unit 14 and the sixth blue LED die unit 16 can be set to 80% to 120% of the radiant flux of the fifth blue LED die unit 15, while the radiant flux of the seventh blue LED die unit 17 can be set to 60% to 100% of the radiant flux of the fifth blue LED die unit 15. That is, in this example, based on setting the radiant flux of the fifth blue LED die unit 15 as 100%, the radiant flux of the fourth blue LED die unit 14 and the sixth blue LED die unit 16 would be 80% to 120%, and the radiant flux of the seventh blue LED die unit 17 would be 60% to 100%. The combined blue light spectrum obtained from these four units resembles that shown in FIG. 5-1. Therefore, in this example, the size of the blue LED die in the seventh blue LED die unit 17 can be smaller than those in the fourth, fifth, and sixth blue LED die units 14, 15, and 16. Additionally, the seventh blue LED die unit 17 can be positioned between the fourth blue LED die unit 14 and the fifth blue LED die unit 15 to facilitate better light mixing among the blue LED die units and ensure optimal light output.

In this example, to further improve the spectral continuity of the LED device, the full width at half maximum of the fifth blue LED die unit 15, the sixth blue LED die unit 16, and the seventh blue LED die unit 17 can also be set to 10 nm to 20 nm, while the full width at half maximum of the fourth blue LED die unit 14 can be set to 15 nm to 25 nm. By coordinating the wavelength bands and full width at half maximum of these four blue LED die units in this example, an LED device with a blue light spectrum distributed according to the desired radiant flux ratio can be achieved.

Correspondingly, in this example, to further enhance the spectral continuity of the LED device, the full width at half maximum of the first cyan phosphor in the first full-spectrum phosphor under blue light excitation can be set to 30 nm to 40 nm, the full width at half maximum of the first green phosphor under blue light excitation to 95 nm to 115 nm, the full width at half maximum of the first yellow phosphor under blue light excitation to 40 nm to 70 nm, and the full width at half maximum of the first red phosphor under blue light excitation to 80 nm to 100 nm.

In this example, through the combination of the aforementioned blue light chipset and the first phosphor gel, a light source with an extremely wide effective synthesized color temperature range can be obtained. For ease of understanding, two specific application scenarios are illustrated below as examples.

In one application scenario, as shown in FIG. 4-2, the LED device in this scenario includes a first base plate 23, with all blue light LED chip units arranged on the same side of the first base plate 23 (e.g., on the front or back surface). A first phosphor gel 22 is applied on the first base plate 23, covering all blue light LED chip units. As illustrated in FIG. 4-2, in this scenario, the fourth blue light LED chip unit 14, fifth blue light LED chip unit 15, sixth blue light LED chip unit 16, and seventh blue light LED chip unit 17 are connected in series (which can alternatively be replaced with parallel or a combination of series-parallel connections) and are all positioned on the first base plate 23. In this scenario, the fourth blue light LED chip unit 14, fifth blue light LED chip unit 15, sixth blue light LED chip unit 16, and seventh blue light LED chip unit 17 may each include only one blue LED die. However, it should be understood that, based on actual requirements, at least one of the fourth blue light LED chip unit 14, fifth blue light LED chip unit 15, sixth blue light LED chip unit 16, and seventh blue light LED chip unit 17 may include two or more blue LED dies. When a blue light LED chip unit contains multiple blue LED dies, the dies within it can be connected in series, parallel, or a combination thereof. In this scenario, the structure of the first base plate 23, whether it is flexible or rigid, as well as its specific shape and size are not limited. The LED device shown in FIG. 4-2 in this scenario is a COB LED device. The color temperature of this LED device can range from 1700K to 13000K. The composition of its first full-spectrum phosphor may be the same as that in the aforementioned examples or slightly adjusted as needed. Its optical performance is largely consistent with the LED devices in the aforementioned examples and will not be reiterated here.

In another application scenario, as shown in FIG. 4-3, the main difference compared to the LED device depicted in FIG. 4-2 is the replacement of the first base plate 23 with the first LED lead frame 20. After this replacement, each blue light LED chip unit is positioned within the reflector cup 21 of the first LED lead frame 20. In this scenario, there are no restrictions on the structure of the first LED lead frame 20 or the specific shape and dimensions of the reflector cup 21. The LED device illustrated in FIG. 4-3 is a surface-mount LED device. In the present application, the color temperature of the LED device can range from 1700K to 13000K. The composition of the first full-spectrum phosphor may be the same as that in the aforementioned examples or slightly adjusted as needed. The optical performance of this LED device is essentially consistent with that of the LED devices in the previous examples and will not be reiterated here.

In other application scenarios of this example, based on the principle of balancing blue light energy distribution, the combination of blue light peak wavelengths for the four sets of blue light LED chip units in FIG. 4-2 or FIG. 4-3 can also be appropriately adjusted within the range of 415 nm to 470 nm. For instance, the blue light peak wavelength of the fourth blue light LED chip unit 14 can be set from 416 nm to 426 nm, the fifth blue light LED chip unit 15 from 431 nm to 441 nm, the sixth blue light LED chip unit 16 from 446 nm to 456 nm, and the seventh blue light LED chip unit 17 from 461 nm to 470 nm. The full width at half maximum range for each group of blue light LED chip units can be adjusted appropriately or remain unchanged, while the first full-spectrum phosphor can be kept unchanged or adjusted slightly. Alternatively, the blue light peak wavelength of the fourth blue light LED chip unit 14 can be specifically set from 415 nm to 430 nm, the fifth blue light LED chip unit 15 from 431 nm to 445 nm, the sixth blue light LED chip unit 16 from 446 nm to 460 nm, and the seventh blue light LED chip unit 17 from 461 nm to 470 nm. The full width at half maximum range for each group of blue light LED chip units can be adjusted appropriately or remain unchanged, and the first full-spectrum phosphor can be kept unchanged or adjusted slightly. Another option is to set the blue light peak wavelength of the fourth blue light LED chip unit 14 from 415 nm to 429 nm, the fifth blue light LED chip unit 15 from 430 nm to 444 nm, the sixth blue light LED chip unit 16 from 445 nm to 459 nm, and the seventh blue light LED chip unit 17 from 460 nm to 468 nm. The full width at half maximum range for each group of blue light LED chip units can be adjusted appropriately or remain unchanged, and the first full-spectrum phosphor can be kept unchanged or adjusted slightly, etc. Testing has shown that the light output effect of the LED device after the above adjustments is similar to that of the LED device shown in FIG. 3-5, meaning it can enhance spectral continuity and similarity to natural light while reducing the blue light peak.

The above examples illustrate the combination methods of three sets and four sets of blue light LED chip units, respectively. However, it should be understood that in this embodiment, five or more sets of blue LED die groups can also be used as needed. A single blue light LED chip unit may include only one blue LED die corresponding to a specific blue light peak wavelength and full width at half maximum range, or it can be configured with multiple blue LED dies as required, which will not be elaborated here. It should also be understood that in this embodiment, the blue light peak wavelength ranges of each set of blue light LED chip units can be set to non-overlapping to ensure the light output effect. Of course, in other examples, the blue light peak wavelength ranges of at least some blue light LED chip units may overlap, as long as the technical issues addressed by this embodiment are essentially resolved. Furthermore, it should be understood that the number of dies included in each set of blue light LED chip units in this embodiment can be the same, or at least one set can have a different number of dies compared to other sets.

In this embodiment, the first cyan phosphor in the above examples may include but is not limited to the oxynitride BaSi2O2N2:Eu2+; the first green phosphor may include but is not limited to the aluminate Lu3Al5O12:Ce3+; the first yellow phosphor may include but is not limited to the silicate Ba2SiO4:Eu2+ or SiAlON:Eu2+, etc.; and the first red phosphor may include but is not limited to the nitride Sr, CaAlSiN3:Eu2+. This embodiment does not impose restrictions on the specific materials of the first cyan phosphor, first green phosphor, first yellow phosphor, and first red phosphor.

For ease of understanding, the following provides an exemplary description of the LED device fabrication process in this embodiment. One fabrication example includes but is not limited to:
S101: the blue LED chipsets are configured.

Using a combination of three sets of blue light LED chip units and taking a color temperature of 5000K as an example, a new chipset configuration is designed: within the blue light peak wavelength range of 415 nm to 470 nm, three sets of blue LED dies with different peak wavelengths are designed. In this setup, the blue light peak wavelengths of the first blue light LED chip unit 11, the second blue light LED chip unit 12, and the third blue light LED chip unit 13 increase sequentially within the range of 430 nm to 465 nm. Specifically, the blue light peak wavelength of the first blue light LED chip unit 11 is set to 430 nm to 440 nm, the second blue light LED chip unit 12 to 445 nm to 455 nm, and the third blue light LED chip unit 13 to 455 nm to 465 nm. Based on setting the radiant flux of the second blue light LED chip unit 12 to 100%, the radiant flux of the first blue light LED chip unit 11 is 80% to 120%, and that of the third blue light LED chip unit 13 is 60% to 100%. Additionally, the full width at half maximum of the second blue light LED chip unit 12 and the third blue light LED chip unit 13 is further set to 10 nm to 20 nm, while that of the first blue light LED chip unit 11 is set to 15 nm to 25 nm.

Using four sets of blue light LED chip units as an example with a color temperature of 5000K, a new die combination scheme is designed: within the blue light peak wavelength range of 415 nm to 470 nm, three sets of blue LED dies with different peak wavelengths are designed. Here, the blue light peak wavelength of the fourth blue light LED chip unit 14 is set to 415 nm to 425 nm, the fifth blue light LED chip unit 15 to 430 nm to 440 nm, the sixth blue light LED chip unit 16 to 445 nm to 455 nm, and the seventh blue light LED chip unit 17 to 460 nm to 470 nm. Further, based on setting the radiant flux of the fifth blue light LED chip unit 15 to 100%, the radiant flux of the fourth and sixth blue light LED chip units 14 and 16 should be 80% to 120%, while that of the seventh blue light LED chip unit 17 should be 60% to 100%. Additionally, set the full width at half maximum of the fifth, sixth, and seventh blue light LED chip units 15, 16, and 17 to 10 nm to 20 nm, and that of the fourth blue light LED chip unit 14 to 15 nm to 25 nm.

Through the combination of wavelength bands and full width at half maximum of the above four sets of blue LED dies in this example, a combined blue light LED chip unit with the blue light spectrum portion distributed according to the desired radiant flux ratio can be achieved.
S102: the matching of the first full-spectrum phosphor is performed.

In this example, to match the aforementioned blue light distribution, it is preferable that the first full-spectrum phosphor includes a first cyan phosphor, a first green phosphor, a first yellow phosphor, and a first red phosphor to combine and synthesize a novel spectral effect. Here, the first cyan phosphor in the selected first full-spectrum phosphor has a peak wavelength range from 490 nm to 510 nm and a full width at half maximum range from 30 nm to 40 nm, and its system may include, but is not limited to, the oxynitride BaSi2O2N2:Eu2+. The first green phosphor has a peak wavelength range from 520 nm to 540 nm and a full width at half maximum range from 95 nm to 115 nm, and its system may include, but is not limited to, the aluminate Lu3A15O12:Ce3+. The first yellow phosphor has a peak wavelength range from 570 nm to 590 nm and a full width at half maximum range from 40 nm to 70 nm, and its system may include, but is not limited to, the silicate Ba2SiO4:Eu2+ or SiAlON:Eu2+. The first red phosphor has a peak wavelength range from 650 nm to 660 nm and a full width at half maximum range from 80 nm to 100 nm, and its system may include, but is not limited to, the nitride Sr, CaAlSiN3:Eu2+.
S103: the semi-finished package carrier is prepared and die attachment is completed.

For example, when the fabricated LED device is an SMD LED lamp bead, the corresponding first LED lead frame can be prepared, and the three or four sets of blue LED dies prepared in S101 can be electrically connected and arranged in the reflector cup of the first LED lead frame.

If the fabricated LED device uses COB as the light source, the corresponding first base plate can be prepared, and the three or four sets of blue LED dies prepared in S101 can be electrically connected and arranged on the first base plate.

In this example, the blue LED dies can be fixed together on the first LED lead frame or the first base plate using, but not limited to, die attach adhesive, and can be baked under conditions not limited to 150° C. for 1H to 2H to fully cure the adhesive. The blue LED dies and between them and the lead frame or the first base plate may also be connected via bonding wires as needed, typically using 0.9 mil 80% Au wires with M or S loop processes. The bonding wire connection method depends on the lead frame structure design and the blue LED die configuration, as long as electrical conduction is achieved.
S104: the fabrication of the first phosphor gel is completed.

Taking the 5000K color temperature preparation scheme of the LED device in FIG. 3-5 as an example: the mass ratio between the first full-spectrum phosphor and the first encapsulant used is 1:3 to 1:1; the ratio among the phosphor combinations is: first cyan phosphor:first green phosphor:first yellow phosphor:first red phosphor-5% to 10%:75% to 85%:0% to 5%:5% to 15%. Taking the 5000K color temperature preparation scheme of the LED device in FIG. 3-4 as an example: the mass ratio between the first full-spectrum phosphor and the first encapsulant used is 1:4 to 1:1; the ratio among the phosphor combinations is: first cyan phosphor:first green phosphor:first yellow phosphor:first red phosphor=5% to 15%:75% to 85%:0% to 5%:5% to 15%. Then, the mixture is uniformly blended using a mixer under oscillation, with typical mixing conditions of 200 s to 400 s at a speed of 1000 rpm to 2000 rpm. By adjusting the concentration ratio between the phosphor combination and the first encapsulant (which may include but is not limited to silicone) and the ratio among the phosphor combinations, optimal spectral schemes for different color temperature ranges can be achieved. It should be understood that the four steps S101 to S104 above do not have a strict sequential order and can be executed either sequentially or with at least some steps performed in parallel, with no restrictions imposed here.
S105: the encapsulation is completed.

By filling the prepared first phosphor gel into the first LED reflector cup or onto the first base plate to cover all blue LED dies, a baking process is performed to cure the first phosphor gel, for example, under baking conditions that may include but are not limited to 150° C. for 3H to 4H. This results in the preparation of the LED device in this embodiment.

Based on the LED device fabricated in this embodiment, an excellent low-blue-light full-spectrum effect that closely matches the natural light spectrum curve can be achieved, significantly enhancing light quality and playing a crucial role in advancing future lighting or display developments.

This embodiment further provides an LED assembly, which includes the aforementioned low-blue-light full-spectrum LED device. In some examples of this embodiment, the LED assembly can be a lighting component for illumination, applicable to but not limited to residential lighting, medical lighting, educational lighting, plant lighting, decorative lighting, traffic lighting, etc. It may include at least one of the COB LED device or surface-mounted LED device mentioned in the above examples. In other examples of this embodiment, the LED assembly can be a display device for screens. When used for display, it can serve as a backlight source for backlit displays or as a direct light source for direct-view displays. Of course, the LED assembly can also function as a backlight or illumination source for keypad devices such as mobile phones, calculators, and keyboards, or be made into camera flashes or fill lights. The above applications are merely a few examples provided in this embodiment, and it should be understood that the applications of the LED assembly in this embodiment are not limited to the aforementioned fields, which will not be exhaustively listed here.

### Embodiment 2

Addressing the issues of poor spectral continuity, high blue light peak, and low similarity to natural light in the existing full-spectrum LED devices described in Embodiment 1, this embodiment provides a novel design for the 400 nm to 500 nm blue light band of LED devices. This design significantly reduces the blue light peak, effectively resolving the poor continuity in the blue light region, bringing it as close as possible to natural light. As a result, the LED device achieves better continuity, enhanced eye protection, and improved color performance. The LED device in this embodiment is a full-spectrum LED device. It should also be understood that the LED device in this embodiment can be implemented independently of other embodiments. For clarity, the following sections of this embodiment provide an illustrative explanation of this full-spectrum LED device.

The full-spectrum LED device provided in this embodiment features excellent spectral continuity, low blue light peak, high similarity to natural light, and a simple structure with low cost. As shown in FIG. 6-1, its light-emitting unit includes a second light-emitting unit, which includes a blue light LED chip unit with a peak wavelength range of 432 nm to 463 nm. In this embodiment, the blue light LED chip unit consists of the eighth blue light LED chip unit 31 and the ninth blue light LED chip unit 32 in FIG. 6-1. Based on the principle of balancing blue light energy distribution, the eighth blue light LED chip unit 31 and the ninth blue light LED chip unit 32 are electrically connected (the connection shown in FIG. 6-1 is in series, but it can also be in parallel in this embodiment). The peak wavelength of the eighth blue light LED chip unit 31 is shorter than that of the ninth blue light LED chip unit 32, and the radiant flux of the ninth blue light LED chip unit is 60% to 100% of that of the eighth blue LED chip unit. This design requires fewer types and quantities of blue LED chips, resulting in a simple structure, low cost, and ease of fabrication. As shown in FIG. 6-1, the encapsulation layer of the full-spectrum LED device includes a second phosphor gel 40 that encapsulates the blue LED chip unit. The second phosphor gel 40 includes a second encapsulant and a second full-spectrum phosphor mixed within the second encapsulant. The spectral coupling between these two sets of blue LED chip units and the second full-spectrum phosphor in the second phosphor gel balances the distribution of blue light energy, reduces the blue light peak in the LED device's spectrum, improves spectral continuity, and enhances the similarity between the LED device and natural light, bringing it closer to natural light for better color effects and improved eye protection for users.

In some examples of this embodiment, the second full-spectrum phosphor includes a second cyan phosphor, a second green phosphor, a second yellow phosphor, and a second red phosphor. The spectral coupling between the eighth blue light LED chip unit 31, the ninth blue light LED chip unit 32, and the second full-spectrum phosphor in the second phosphor gel 40 further reduces the blue light peak in the LED device's spectrum, improves spectral continuity, and enhances the similarity between the LED device and natural light, bringing it closer to natural light for better color effects.

For blue LED chips, the wavelength of the blue light is directly related to the In component content of the chip. Therefore, in this embodiment, the peak wavelength of the blue LED chip can also be set by controlling the In component of the chip. Additionally, the size and type settings of the blue LED chip in this embodiment can refer to, but are not limited to, the aforementioned Embodiment 1, and will not be repeated here.

To further enhance the spectral continuity of the LED device in this example, this embodiment conFIGS. the second full-spectrum phosphor to include a second cyan phosphor, a second green phosphor, a second yellow phosphor, and a second red phosphor. In some application scenarios of this example, the second full-spectrum phosphor can be composed of the second cyan phosphor, second green phosphor, second yellow phosphor, and second red phosphor, requiring fewer types of phosphors at lower costs and simpler mixing ratios. For instance, in some examples, to match the aforementioned blue light distribution, the selected second cyan phosphor can be set to have an emission peak wavelength range of 490 nm to 510 nm under blue light excitation, the second green phosphor to have an emission peak wavelength range of 520 nm to 540 nm, the second yellow phosphor to have an emission peak wavelength range of 570 nm to 590 nm, and the second red phosphor to have an emission peak wavelength range of 650 nm to 660 nm. Of course, it should be understood that in some application examples, at least one of the second cyan phosphor, second green phosphor, second yellow phosphor, or second red phosphor can be equivalently replaced with corresponding QDs.

To further enhance the spectral continuity of the LED device in this example, in some application scenarios of this example, the peak wavelength range of the eighth blue light LED chip unit 31 can be set to 432 nm to 442 nm, and the peak wavelength range of the ninth blue light LED chip unit 32 can be set to 453 nm to 463 nm. The radiant flux of the ninth blue light LED chip unit 32 is 60% to 100% of that of the eighth blue light LED chip unit 31. The definition of radiant flux in this example refers to Embodiment 1 above. That is, in this example, based on setting the radiant flux of the eighth blue light LED chip unit 31 to 100%, the radiant flux of the ninth blue light LED chip unit 32 is 60% to 100%. The combined blue light spectrum obtained from these two units is shown in FIG. 6-4. Therefore, in this example, the size of the blue LED chips in the ninth blue light LED chip unit 32 can be smaller than those in the eighth blue light LED chip unit 31. This combination of different-sized chips not only allows for more flexible chip layout but also helps reduce costs.

In this example, to further improve the spectral continuity of the LED device, the full width at half maximum range of the eighth blue light LED chip unit 31 can be set to 15 nm to 25 nm, and the full width at half maximum range of the ninth blue light LED chip unit 32 can be set to LED to 10 nm. The definition of the full width at half maximum range in this example refers to Embodiment 1 above. Thus, the full width at half maximum range of the blue LED chips can be flexibly adjusted by controlling their growth rate. By coordinating the wavelength bands and full width at half maximum ranges of the eighth blue light LED chip unit 31 and the ninth blue light LED chip unit 32 in this example, an LED device with the blue light spectrum portion distributed according to the desired radiant flux ratio can be achieved.

Correspondingly, in this example, to further enhance the spectral continuity of the LED device, the full width at half maximum of the second cyan phosphor in the second full-spectrum phosphor under blue light excitation can be set to 30 nm to 40 nm, the full width at half maximum of the second green phosphor under blue light excitation to 95 nm to 115 nm, the full width at half maximum of the second yellow phosphor under blue light excitation to 40 nm to 70 nm, and the full width at half maximum of the second red phosphor under blue light excitation to 80 nm to 100 nm.

In this embodiment, the combination of the aforementioned blue light LED chip unit and the second phosphor gel can produce a light source with an extremely wide color temperature range. Since the excitation efficiency of the blue LED chip on the second full-spectrum phosphor decreases as the wavelength increases, and different second full-spectrum phosphors have fixed excitation efficiency curves, this embodiment achieves a full-spectrum LED device with low blue light, high spectral continuity, and close resemblance to natural light by designing the spectral energy and wavelength pairing of the blue LED chip. For clarity, the following examples illustrate specific blue LED chip configurations.

### Example 1

In this example, the peak wavelength range of the eighth blue light LED chip unit 31 in the full-spectrum LED device is 432 nm to 442 nm, and the peak wavelength range of the ninth blue light LED chip unit 32 is 453 nm to 463 nm. The full width at half maximum of the eighth blue light LED chip unit 31 ranges from 15 nm to 25 nm, while that of the ninth blue light LED chip unit 32 ranges from 10 nm to 20 nm. The radiant flux of the ninth blue light LED chip unit 32 is 60% to 100% of that of the eighth blue light LED chip unit 31. The second cyan phosphor in the second full-spectrum phosphor selected for the full-spectrum LED device has an emission peak wavelength range of 490 nm to 510 nm under blue light excitation, with a full width at half maximum of 30 nm to 40 nm. The second green phosphor exhibits an emission peak wavelength range of 520 nm to 540 nm under blue light excitation, with a full width at half maximum of 95 nm to 115 nm. The second yellow phosphor has an emission peak wavelength range of 570 nm to 590 nm under blue light excitation, with a full width at half maximum of 40 nm to 70 nm. The second red phosphor shows an emission peak wavelength range of 650 nm to 660 nm under blue light excitation, with a full width at half maximum of 80 nm to 100 nm. Testing reveals that the full-spectrum LED device, achieved by combining the aforementioned blue LED chip units and the second phosphor gel, significantly improves spectral continuity and similarity to natural light within the effective color temperature range of 2700K to 6500K. The blue light peak is greatly reduced, and both Rf and Rg are substantially enhanced.

For example, one application scenario is illustrated in FIG. 6-2, which shows a full-spectrum LED device. It further includes a second LED lead frame 41, comprising a second reflector cup 42 (also referred to as a reflective cavity or accommodating cavity). An eighth blue light LED chip unit 31 and a ninth blue light LED chip unit 32 are both placed within the second reflector cup 42 and connected in series. At least part of the second phosphor gel is located inside the second reflector cup 42, covering all blue LED chip units. In this scenario, the peak wavelength range of the eighth blue light LED chip unit 31 is 432 nm to 437 nm, while that of the ninth blue light LED chip unit 32 is 458 nm to 463 nm. The full width at half maximum of the eighth blue light LED chip unit 31 ranges from 15 nm to 25 nm, and that of the ninth blue light LED chip unit 32 ranges from 10 nm to 20 nm. The radiant flux of the eighth blue light LED chip unit 31 is 100%, whereas that of the ninth blue light LED chip unit 32 ranges from 60% to 90% or 60% to 100%. The second full-spectrum phosphor's cyan phosphor, under blue light excitation, has an emission peak wavelength range of 490 nm to 510 nm and a full width at half maximum of 30 nm to 40 nm. The second green phosphor, under blue light excitation, has an emission peak wavelength range of 520 nm to 540 nm, with a full width at half maximum of 95 nm to 115 nm. The second yellow phosphor, under blue light excitation, has an emission peak wavelength range of 570 nm to 590 nm and a full width at half maximum of 40 nm to 70 nm. The second red phosphor, under blue light excitation, has an emission peak wavelength range of 650 nm to 660 nm, with a full width at half maximum of 80 nm to 100 nm. In this example, the eighth blue light LED chip unit 31 and the ninth blue light LED chip unit 32 may each consist of only one blue LED chip, requiring just two blue LED chips in combination. This simplifies the structure of the full-spectrum LED device to the utmost and minimizes chip costs. However, it should be understood that, depending on actual needs, at least one of the eighth blue light LED chip unit 31 and the ninth blue light LED chip unit 32 may include more than two blue LED chips. When a blue light LED chip unit contains multiple blue LED chips, they can be connected in series, parallel, or a combination of both. In the present application scenario, the structure of the second LED lead frame 41 and the specific shape and dimensions of the second reflector cup 42 are not restricted. The full-spectrum LED device shown in FIG. 6-2 in this scenario is a surface-mount LED device. When the color temperature of the full-spectrum LED device in FIG. 6-2 is 2700 k or 3000 k, the mass ratio of the second full-spectrum phosphor to the second encapsulant is 1:1 to 2:1. When the color temperature is 4000 k, the mass ratio of the second full-spectrum phosphor to the second encapsulant is 1:2 to 1:1. For color temperatures of 5000K, 5700K, or 6500K, the mass ratio of the second full-spectrum phosphor to the second encapsulant is 1:3 to 1:1, as shown in Table 8 below. At these color temperatures, the proportions of the second cyan phosphor, second green phosphor, second yellow phosphor, and second red phosphor in the second full-spectrum phosphor are detailed in Table 8.

TABLE 8

| | Color Temperature | | | | | |
|---|---|---|---|---|---|---|
| Category | 2700K | 3000K | 4000K | 5000K | 5700K | 6500K |
| Mass ratio of the | 1:1 to | 1:1 to | 1:2 to | 1:3 to | 1:3 to | 1:3 to |
| second full-spectrum | 2:1 | 2:1 | 1:1 | 1:1 | 1:1 | 1:1 |
| phosphor to the | | | | | | |
| second encapsulant | | | | | | |
| Proportion of the | 0% to | 0% to | 0% to | 5% to | 5% to | 10% to |
| second cyan phosphor | 10% | 10% | 10% | 15% | 15% | 20% |
| Proportion of the | 75% to | 75% to | 75% to | 75% to | 80%- | 70% to |
| second green phosphor | 90% | 90% | 95% | 85% | 90% | 80% |
| Proportion of the | 0% to | 0% to | 0% to | 0% to | 0% to | 0% to |
| second yellow phosphor | 5% | 5% | 5% | 5% | 5% | 5% |
| Proportion of the | 5% to | 10% to | 5% to | 5% to | 5% to | 5% to |
| second red phosphor | 15% | 20% | 15% | 15% | 15% | 15% |

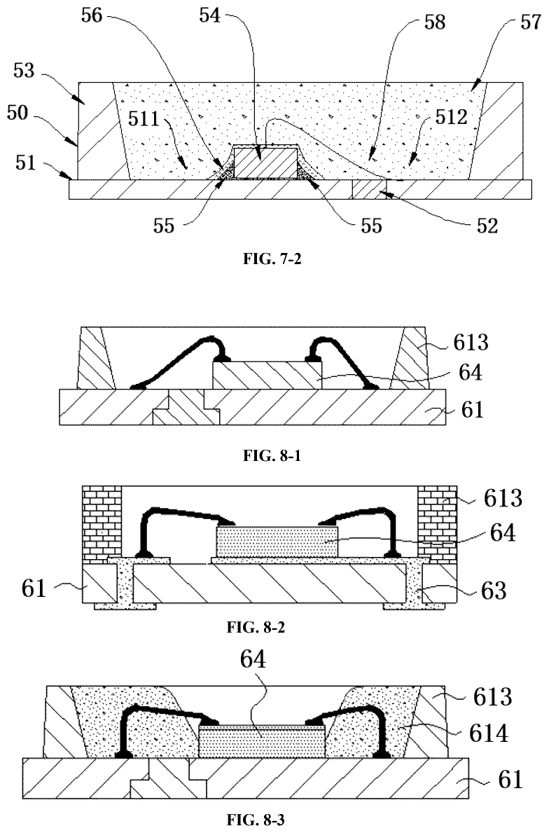

The full-spectrum LED device shown in FIG. 6-2 offers advantages such as low blue light, spectral continuity, and high similarity to natural light. For clarity, its optical performance at a color temperature of 5000K is illustrated below. Under the TM-30-15 standard, the evaluation results of the full-spectrum LED device (hereinafter referred to as the “new light source”) at 5000K color temperature are shown in FIGS. 6-5 to 6-6. FIG. 6-5 displays the spectral power distribution of this full-spectrum LED device, while FIG. 6-6 presents a spectral comparison by incorporating the data from FIG. 6-5 into the framework of FIGS. 1-3 from the aforementioned embodiment. The hue parameters measured under the TM-30-15 standard are listed in Table 9. FIG. 6-7 illustrates the Rf-Rg diagram, where the black dot represents the reference light source (i.e., natural light), and FIG. 6-8 shows the Rf hue diagram. As seen in FIG. 6-8, the Rf values of the new light source for all standard colors (indicated by the horizontal axis in FIG. 6-8) are significantly above 90, mostly ranging between 95 and 100. Combining the insights from FIGS. 6-7 and 6-8, the value of Rg also predominantly falls between 95 and 100. Furthermore, according to the test results in Table 9, when Rf is 98, the value of Rg can reach 100.

As clearly demonstrated by the FIGS. above, the spectral continuity of the full-spectrum LED device in FIG. 6-2 and its similarity to natural light have significantly improved, with a substantial reduction in blue light peak intensity. Additionally, both Rf and Rg have seen considerable enhancement.

TABLE 9

| Tone | Mainstream | Conventional | New Light |
|---|---|---|---|
| Parameters | Light Sources | Ra90 | Sources |
| Rg | 99 | 98 | 100 |
| Rf | 92 | 89 | 98 |
| 1 | 94.1 | 88.9 | 98 |
| 2 | 97.3 | 93.1 | 99 |
| 3 | 93.6 | 90.3 | 98 |
| 4 | 90.1 | 91.4 | 97 |
| 5 | 89.1 | 91.4 | 97 |
| 6 | 94.7 | 95.5 | 98 |
| 7 | 92.3 | 93.9 | 98 |
| 8 | 90.4 | 90.2 | 98 |
| 9 | 90.3 | 87.9 | 97 |
| 10 | 90.3 | 81.9 | 98 |
| 11 | 89.3 | 80.3 | 97 |
| 12 | 93.2 | 88.1 | 97 |
| 13 | 92.8 | 91.4 | 96 |
| 14 | 93.9 | 92.2 | 98 |
| 15 | 84.7 | 81.4 | 95 |
| 16 | 94.4 | 89 | 97 |

In this embodiment, the color vector diagram of the full-spectrum LED device shown in FIG. 6-2 can be referred to FIGS. 5-6 in the first embodiment above. The two circles A0 and A1 perfectly overlap, meaning the light emitted by the full-spectrum LED device in FIG. 6-2 has virtually no difference in color rendering compared to the reference light source (natural light). In other words, the light emitted by the full-spectrum LED device in FIG. 6-2 can closely approximate natural light, thereby achieving better continuity effects. Its similarity to natural light is significantly enhanced, also resulting in improved eye protection and color performance. The ASD value calculated for the light emitted by the full-spectrum LED device in FIG. 6-2, based on the above formula (1), is shown in Table 10, which further validates this from another perspective.

TABLE 10

| | Mainstream | Conventional | New light |
|---|---|---|---|
| Parameter | light source | Ra90 | source |
| ASD | 23.62% | 28.01% | 16.94% |

In another application scenario, as shown in FIG. 6-3, the full-spectrum LED device in this scenario includes a second base plate 43, with the eighth blue light LED chip unit 31 and the ninth blue light LED chip unit 32 arranged on the same side of the second base plate 43 (e.g., on the front or back side) and connected in series. The second phosphor gel 40 is applied on the second base plate 43, covering the eighth blue light LED chip unit 31 and the ninth blue light LED chip unit 32. As illustrated in FIG. 6-3, in this scenario, the peak wavelength range of the eighth blue light LED chip unit 31 is 432 nm to 437 nm, while that of the ninth blue light LED chip unit 32 is 458 nm to 463 nm. The full width at half maximum of the eighth blue light LED chip unit 31 ranges from 15 nm to 25 nm, and that of the ninth blue light LED chip unit 32 ranges from 10 nm to 20 nm. The radiant flux of the eighth blue light LED chip unit 31 is 100%, whereas that of the ninth blue light LED chip unit 32 ranges from 60% to 80% or 60% to 100%. The second cyan phosphor in the second full-spectrum phosphor has an emission peak wavelength range of 490 nm to 510 nm under blue light excitation, with a full width at half maximum of 30 nm to 40 nm. The second green phosphor has an emission peak wavelength range of 520 nm to 540 nm under blue light excitation, with a full width at half maximum of 95 nm to 115 nm. The second yellow phosphor has an emission peak wavelength range of 570 nm to 590 nm under blue light excitation, with a full width at half maximum of 40 nm to 70 nm. The second red phosphor has an emission peak wavelength range of 650 nm to 660 nm under blue light excitation, with a full width at half maximum of 80 nm to 100 nm. In this example, the eighth blue light LED chip unit 31 and the ninth blue light LED chip unit 32 may each consist of only one blue LED chip, requiring just two blue LED chips in combination. This simplifies the structure of the full-spectrum LED device to the utmost and minimizes chip costs. However, it should be understood that, based on actual needs, at least one of the eighth blue light LED chip unit 31 and the ninth blue light LED chip unit 32 may include more than two blue LED chips. In this scenario, there are no restrictions on the structure of the second base plate 43, whether it is flexible or rigid, or its specific shape and dimensions. The full-spectrum LED device shown in FIG. 6-3 in this scenario is a COB (Chip On Board) LED device. When the color temperature of the full-spectrum LED device in FIG. 6-3 is 2700K or 3000K, the mass ratio of the second full-spectrum phosphor to the second encapsulant is 1:2 to 1:1. When the color temperature is 4000K, the mass ratio of the second full-spectrum phosphor to the second encapsulant is 1:3 to 1:1. When the color temperature is 5000 k, 5700 k, or 6500 k, the mass ratio of the second full-spectrum phosphor to the second encapsulant is 1:4 to 1:1. At these color temperatures, the proportions of the second cyan phosphor, second green phosphor, second yellow phosphor, and second red phosphor in the second full-spectrum phosphor are as shown in Table 11 below.

TABLE 11

| | Color Temperature | | | | | |
|---|---|---|---|---|---|---|
| Category | 2700K | 3000K | 4000K | 5000K | 5700K | 6500K |
| Mass ratio of the | 1:2 to | 1:2 to | 1:3 to | 1:4 to | 1:4 to | 1:4 to |
| second full-spectrum | 1:1 | 1:1 | 1:1 | 1:1 | 1:1 | 1:1 |
| phosphor to the | | | | | | |
| second encapsulant | | | | | | |
| Proportion of the | 0% to | 0% to | 0% to | 5% to | 5% to | 10% to |
| second cyan phosphor | 10% | 10% | 10% | 15% | 15% | 20% |
| Proportion of the | 75% to | 75% to | 75% to | 75% to | 80%- | 70% to |
| second green phosphor | 90% | 90% | 95% | 85% | 90% | 80% |
| Proportion of the | 0% to | 0% to | 0% to | 0% to | 0% to | 0% to |
| second yellow phosphor | 5% | 5% | 5% | 5% | 5% | 5% |
| Proportion of the | 5% to | 10% to | 5% to | 5% to | 5% to | 5% to |
| second red phosphor | 15% | 20% | 15% | 15% | 15% | 15% |

The full-spectrum LED device shown in FIG. 6-3 also offers advantages such as low blue light, spectral continuity, and high similarity to natural light. Tests indicate that the optical performance of the full-spectrum LED device in FIG. 6-3 is essentially consistent with that of the full-spectrum LED device in FIG. 6-2 at a color temperature of 5000K. Additionally, the spectral power distribution diagrams for both devices at 2700K, 3000K, 4000K, 5700K, and 6500K are shown in FIGS. 6-9 to 6-13, respectively (refer to the curves labeled “New Solution” in the figures).

### Example 2

In this example, the peak wavelength range of the eighth blue light LED chip unit 31 in the full-spectrum LED device is 432 nm to 445 nm, while the peak wavelength range of the ninth blue light LED chip unit 32 is 446 nm to 463 nm. The full width at half maximum of the eighth blue light LED chip unit 31 ranges from 15 nm to 25 nm, and that of the ninth blue light LED chip unit 32 ranges from 10 nm to 20 nm. The radiant flux of the eighth blue light LED chip unit 31 is 100%, while that of the ninth blue light LED chip unit 32 is 70% to 80% or 60% to 100%. The second cyan phosphor in the second full-spectrum phosphor selected for the full-spectrum LED device has an emission peak wavelength range of 490 nm to 510 nm under blue light excitation, with a full width at half maximum of 30 nm to 40 nm. The second green phosphor has an emission peak wavelength range of 520 nm to 540 nm under blue light excitation, with a full width at half maximum of 95 nm to 115 nm. The second yellow phosphor has an emission peak wavelength range of 570 nm to 590 nm under blue light excitation, with a full width at half maximum of 40 nm to 70 nm. The second red phosphor has an emission peak wavelength range of 650 nm to 660 nm under blue light excitation, with a full width at half maximum of 80 nm to 100 nm. The full-spectrum LED device, obtained by combining the aforementioned blue LED chip units and the second phosphor gel, was tested to demonstrate light output characteristics in the synthesized correlated color temperature range of 2700K to 6500K that are fundamentally consistent with the device illustrated in FIG. 6-2. That is, both can improve spectral continuity and similarity to natural light, reduce the blue light peak, and significantly enhance both Rf and Rg.

### Example 3

In this example, the peak wavelength range of the eighth blue light LED chip unit 31 in the full-spectrum LED device is 435 nm to 440 nm, while the peak wavelength range of the ninth blue light LED chip unit 32 is 442 nm to 463 nm. The full width at half maximum of the eighth blue light LED chip unit 31 ranges from 15 nm to 25 nm, and that of the ninth blue light LED chip unit 32 ranges from 10 nm to 20 nm. The radiant flux of the eighth blue light LED chip unit 31 is 100%, while that of the ninth blue light LED chip unit 32 is 60% to 80% or 60% to 100%. The second cyan phosphor in the second full-spectrum phosphor selected for the full-spectrum LED device has an emission peak wavelength range of 490 nm to 510 nm under blue light excitation, with a full width at half maximum of 35 nm to 40 nm. The second green phosphor has an emission peak wavelength range of 520 nm to 540 nm under blue light excitation, with a full width at half maximum of 100 nm to 115 nm. The second yellow phosphor has an emission peak wavelength range of 570 nm to 590 nm under blue light excitation, with a full width at half maximum of 45 nm to 70 nm. The second red phosphor has an emission peak wavelength range of 650 nm to 660 nm under blue light excitation, with a full width at half maximum of 85 nm to 100 nm. The full-spectrum LED device obtained by combining the aforementioned blue LED chip units and the second phosphor gel was tested to demonstrate light output characteristics in the synthesized correlated color temperature range of 2700K to 6500K that are fundamentally consistent with the device illustrated in FIG. 6-2. That is, both can improve spectral continuity and similarity to natural light, reduce the blue light peak, and significantly enhance both Rf and Rg.

### Example 4

In this example, the peak wavelength range of the eighth blue light LED chip unit 31 in the full-spectrum LED device is 432 nm to 437 nm, and the peak wavelength range of the ninth blue light LED chip unit 32 is 458 nm to 463 nm. The full width at half maximum of the eighth blue light LED chip unit 31 ranges from 15 nm to 20 nm, while that of the ninth blue light LED chip unit 32 ranges from 10 nm to 18 nm. The radiant flux of the ninth blue light LED chip unit 32 is 60% to 100% of that of the eighth blue light LED chip unit 31. The second cyan phosphor in the second full-spectrum phosphor selected for the full-spectrum LED device has an emission peak wavelength range of 490 nm to 510 nm under blue light excitation, with a full width at half maximum of 35 nm to 400 nm under blue light excitation. The second green phosphor has an emission peak wavelength range of 520 nm to 540 nm under blue light excitation, with a full width at half maximum of 100 nm to 115 nm under blue light excitation. The second yellow phosphor has an emission peak wavelength range of 570 nm to 590 nm under blue light excitation, with a full width at half maximum of 45 nm to 70 nm under blue light excitation. The second red phosphor has an emission peak wavelength range of 650 nm to 660 nm under blue light excitation, with a full width at half maximum of 85 nm to 100 nm under blue light excitation. The full-spectrum LED device, obtained by combining the aforementioned blue LED chip units and the second phosphor gel, was tested to demonstrate light output characteristics in the synthesized correlated color temperature range of 2700K to 6500K that are fundamentally consistent with the device illustrated in FIG. 6-2. That is, both can enhance spectral continuity and similarity to natural light, reduce the blue light peak, and significantly improve Rf and Rg.

### Example 5

In this example, the peak wavelength range of the eighth blue light LED chip unit 31 in the full-spectrum LED device is 432 nm to 437 nm, and the peak wavelength range of the ninth blue light LED chip unit 32 is 453 nm to 463 nm. The full width at half maximum range of the eighth blue light LED chip unit 31 is 20 nm to 25 nm, and the full width at half maximum range of the ninth blue light LED chip unit 32 is 15 nm to 20 nm. The radiant flux of the ninth blue light LED chip unit 32 is 60% to 100% of that of the eighth blue light LED chip unit 31. The second cyan phosphor in the second full-spectrum phosphor selected for the full-spectrum LED device has an emission peak wavelength range of 500 nm to 510 nm under blue light excitation, with a full width at half maximum of 30 nm to 40 nm under blue light excitation. The second green phosphor has an emission peak wavelength range of 530 nm to 540 nm under blue light excitation, with a full width at half maximum of 95 nm to 115 nm under blue light excitation. The second yellow phosphor has an emission peak wavelength range of 580 nm to 590 nm under blue light excitation, with a full width at half maximum of 40 nm to 70 nm under blue light excitation. The second red phosphor has an emission peak wavelength range of 650 nm to 660 nm under blue light excitation, with a full width at half maximum of 80 nm to 100 nm under blue light excitation. The full-spectrum LED device, obtained by combining the aforementioned blue LED chip units and the second phosphor gel, was tested to demonstrate light output characteristics in the synthesized correlated color temperature range of 2700K to 6500K that are fundamentally consistent with the device illustrated in FIG. 6-2. That is, both can enhance spectral continuity and similarity to natural light, reduce the blue light peak, and significantly improve Rf and Rg.

In this embodiment, as shown in FIGS. 6-14, the main difference compared to the full-spectrum LED device depicted in FIG. 6-1 lies in the eighth blue light LED chip unit 31 and the ninth blue light LED chip unit 32 being connected in parallel instead of series. The full-spectrum LED device illustrated in FIG. 6-14 can also be applied to, but not limited to, the aforementioned Examples 1 through 5, and its light emission performance can achieve the same level as that of the full-spectrum LED device shown in FIG. 6-1, which will not be elaborated further here.

Thus, it can be inferred that within the given performance parameter ranges of the blue LED chips, the performance ranges of the second full-spectrum phosphor, and the mass ratio between the second full-spectrum phosphor and the second encapsulant in this embodiment, flexible adjustments can be made as needed to obtain the corresponding full-spectrum LED device. The resulting full-spectrum LED device exhibits improved spectral continuity, similarity to natural light, and enhanced Rf and Rg parameters, along with reduced blue light peaks. This will not be detailed further. Additionally, in this embodiment, the peak wavelength ranges of the eighth blue light LED chip unit 31 and the ninth blue light LED chip unit 32 are preferably non-overlapping to ensure optimal light emission. However, if the technical issues addressed by this embodiment can be resolved, the peak wavelength ranges of the eighth and ninth blue LED chip units may partially overlap as required, which also falls within the scope of this embodiment. It should also be understood that the number of LED chips included in each of the eighth and ninth blue LED chip units 31 and 32 may be the same or different.

In this embodiment, the second cyan phosphor in the above examples may adopt, but is not limited to, the oxynitride BaSi2O2N2:Eu2+; the second green phosphor may adopt, but is not limited to, the aluminate Lu3 A15O12:Ce3+; the second yellow phosphor may adopt, but is not limited to, the silicate Ba2SiO4:Eu2+ or SiAlON:Eu2+; and the second red phosphor may adopt, but is not limited to, the nitride Sr, CaAlSiN3:Eu2+. This embodiment imposes no restrictions on the specific materials of the second cyan, green, yellow, and red phosphors.

For ease of understanding, the following provides an illustrative description of the fabrication process of the full-spectrum LED device in this embodiment. One fabrication example includes, but is not limited to:
S201: the blue LED chip units are configured.

For example, the peak wavelength range of the eighth blue light LED chip unit is selected to be 432 nm to 437 nm, the peak wavelength range of the ninth blue light LED chip unit to be 458 nm to 463 nm, the full width at half maximum range of the eighth blue light LED chip unit to be 15 nm to 25 nm, the full width at half maximum range of the ninth blue light LED chip unit to be 10 nm to 20 nm, and the radiant flux of the ninth blue light LED chip unit to be 60% to 100% of the radiant flux of the eighth blue light LED chip unit 31.
S202: the matching of the second full-spectrum phosphor is performed.

In this example, to match the above blue light distribution, the second full-spectrum phosphor preferably includes a second cyan phosphor, a second green phosphor, a second yellow phosphor, and a second red phosphor to combine and create a new spectral effect. For instance, here, the peak wavelength range of the second cyan phosphor in the second full-spectrum phosphor is selected to be 490 nm to 510 nm, with a full width at half maximum range of 30 nm to 40 nm, and its system may include but is not limited to oxynitride BaSi2O2N2:Eu2+; the peak wavelength range of the second green phosphor is 520 nm to 540 nm, with a full width at half maximum range of 95 nm to 115 nm, and its system may include but is not limited to aluminate Lu3A15O12:Ce3+; the peak wavelength range of the second yellow phosphor is 570 nm to 590 nm, with a full width at half maximum range of 40 nm to 70 nm, and its system may include but is not limited to silicate Ba2Si04:Eu2+ or SiAlON:Eu2+, etc.; and the peak wavelength range of the second red phosphor is 650 nm to 660 nm, with a full width at half maximum range of 80 nm to 100 nm, and its system may include but is not limited to nitride Sr, CaAlSiN3:Eu2+.
S203: the semi-finished package carrier is prepared and die bonding is completed.

For example, if the full-spectrum LED device being manufactured is a surface-mount LED lamp bead, the corresponding second LEDlead frame can be prepared accordingly. The eighth blue light LED chip unit and the ninth blue light LED chip unit prepared in S201 are placed in the second reflector cup of the second LEDlead frame, and the two are connected in series or parallel;

If the full-spectrum LED device to be fabricated uses COB as the light source, the second base plate can be prepared accordingly, and the eighth blue light LED chip unit and ninth blue light LED chip unit prepared in S201 can be connected in series and arranged on the second base plate.

In this example, the blue LED chips can be fixed together onto the second LED lead frame or second base plate using, but not limited to, die attach adhesive, and baked under conditions not limited to 150° C. for 1H to 2H until the adhesive is fully cured. The blue LED chips and their connections to the lead frame or second base plate can also be bonded with wires as needed, typically using 0.9 mil 80% Au wires and employing M or S wire arc processes. The bonding method depends on the carrier structure design and blue LED chip configuration, ensuring circuit continuity.
S204: the preparation of the second phosphor gel is completed.

Taking the 5000K color temperature preparation scheme of the full-spectrum LED device shown in FIG. 6-2 as an example: the mass ratio between the second full-spectrum phosphor and the second encapsulant solution is 1:3 to 1:1; the ratio among the second full-spectrum phosphor combinations is: second cyan phosphor: second green phosphor: second yellow phosphor: second red phosphor=5% to 10%:75% to 85%:0% to 5%:5% to 15%. Taking the 5000K color temperature preparation scheme of the full-spectrum LED device shown in FIG. 6-3 as an example: the mass ratio between the second full-spectrum phosphor and the second encapsulant solution is 1:4 to 1:1; the ratio among the second full-spectrum phosphor combinations is: second cyan phosphor: second green phosphor: second yellow phosphor: second red phosphor-5% to 15%:75% to 85%:0% to 5%:5% to 15%. The mixture is then homogenized using a mixer, typically under conditions of 200 s to 400 s at 1000 rpm to 2000 rpm. By adjusting the concentration ratio between the second full-spectrum phosphor combination and the second encapsulant (e.g., silicone, though not limited to it) and the inter-phosphor ratios of the second full-spectrum phosphor combination, optimal spectral solutions for different color temperature ranges can be achieved. It should be noted that the four steps S201 to S204 do not strictly follow a sequential order and can be executed either consecutively or with at least some steps performed in parallel, with no restrictions imposed here.
S205: the packaging is completed.

The prepared second phosphor gel is encapsulated in the second reflector cup of the second LED lead frame or on the second base plate to cover each blue LED chip, and a baking process is performed to cure the second phosphor gel. For example, the baking conditions may include but are not limited to baking at 150° C. for 3H to 4H. This yields the preparation of the full-spectrum LED device in this embodiment.

Based on the full-spectrum LED device produced in this embodiment, an excellent low-blue-light full-spectrum effect that closely fits the natural light spectrum curve can be achieved, significantly improving light quality and playing a crucial role in advancing future lighting or display technologies.

This embodiment further provides an LED assembly, which includes the aforementioned low-blue-light full-spectrum LED device. The specific application fields of this LED assembly refer to, but are not limited to, the LED assembly described in the first embodiment above, and thus will not be reiterated here.

### Embodiment 3

In related art, a LED packaging device includes an LED lead frame, LED chips, a bonding layer, bonding wires, and encapsulant. This LED packaging technology first places a bonding layer in the cup of the LED lead frame, then mounts the LED chips onto the bonding layer, followed by soldering the bonding wires. Subsequently, encapsulant is injected into the cup post-wire bonding, and baking is performed to cure it, resulting in the finished LED. When silicone is used as the encapsulant, its high moisture and oxygen permeability allows humidity to seep in during long-term operation, causing the bonding layer and the functional zone at the bottom of the cup to fail, leading to LED failure. When epoxy resin is used as the encapsulant, its moisture and oxygen permeability is relatively lower, but its higher stress generates significant thermal stress during high-temperature reflow soldering of the LED packaging device, potentially breaking the bonding wires or delaminating the bonding layer at the chip bottom from the base plate, also causing LED failure. Thus, the aforementioned LED packaging technologies have notable flaws that urgently require improvement. The LED device provided in this embodiment effectively reduces the impact of moisture, oxygen, and thermal stress on its performance, ensuring greater overall stability and extending its service life.

It should also be understood that the LED device in this embodiment can be implemented independently of other embodiments. For clarity, the following provides an illustrative explanation of this LED device.

Referring to FIGS. 7-1 and 7-2, the LED device provided in this embodiment includes a third LED lead frame 50. The light-emitting unit of the LED device includes a third light-emitting unit, which consists of an LED chip 54. The third LED lead frame 50 has a chip mounting area, where a bonding layer 55 is disposed, and the LED chip 54 is placed on the bonding layer 55. The LED device features a resin protective layer 56 and an encapsulation gel layer 57. The resin protective layer 56 covers the LED chip 54 and the bonding layer 55. The bonding strength between the LED chip 54 and the third LED lead frame 50 is enhanced by covering the bonding layer 55 with the resin protective layer 56. The encapsulation gel layer 57 covers the LED chip 54 and the resin protective layer 56. The oxygen and moisture permeability of the resin protective layer 56 is lower than that of the encapsulation gel layer 57. In this embodiment, the oxygen and moisture transmission rates of the resin protective layer 56 are specifically lower than those of the encapsulation gel layer 57. In detail, the resin protective layer 56 is formed by curing epoxy resin adhesive, while the encapsulation gel layer 57 is formed by curing silicone resin or silicone gel. Alternatively, the resin protective layer 56 may be formed by curing silicone resin, and the encapsulation gel layer 57 by curing silicone gel. Compared to the prior art, where only silicone gel is injected into the LED lead frame to cover the LED chip and bonding layer, the epoxy resin or silicone resin used as the resin protective layer 56 in this embodiment exhibits lower moisture and oxygen transmission rates than the silicone resin or silica gel used as the encapsulant. This effectively prevents the LED chip and bonding layer in the LED device from being easily penetrated by moisture and oxygen, thereby avoiding the phenomenon of dead lights. On the other hand, compared to the structure in the prior art where only epoxy resin adhesive is injected into the LED lead frame to encapsulate the LED chip and bonding layer, although epoxy resin has low oxygen and moisture permeability, it generates higher thermal stress. When encapsulating high-power chips, the thermal stress from the chips can cause the epoxy resin to crack, exposing the cracks to the external environment and allowing moisture to penetrate the LED device, compromising the bonding strength between the LED chip and the LED lead frame. Additionally, cracks in the epoxy resin exposed externally can adversely affect optical performance. In this embodiment, epoxy resin is used only as the resin protective layer, which is applied near the bonding layer 55 and the LED chip 54. The exterior of the resin protective layer 56 is covered with silicone resin or gel. Due to its low oxygen and moisture permeability, the resin protective layer 56 reduces the likelihood of delamination between the LED chip 54 and the third LED lead frame 50 at the bonding layer 55. Meanwhile, the silicone resin or gel, with its lower thermal stress, minimizes the risk of surface cracking in the encapsulation gel layer 57. Thus, the LED device in this embodiment achieves higher thermal resistance, better hermeticity, and a longer service life.

Optionally, the resin protective layer 56 further covers the front surface and side surfaces of the LED chip 54. In some applications, the LED chip 54 is typically covered by the resin protective layer 56, but the thickness of the resin protective layer above the LED chip 54 is not specifically limited.

Optionally, the bonding layer 55 has a circular shape, and the peripheral edge of the bottom of the LED chip 54 is located within the bonding layer 55. Specifically, in this embodiment, the bonding layer is arranged in the chip mounting area, forming a bonding layer 55 with a (nearly) circular shape, while the peripheral edge of the bottom of the LED chip 54 is square and located within the bonding layer 55.

Optionally, the thickness of the resin protective layer 56 ranges from 10 μm to 60 μm, which can effectively enhance the bonding force between the bonding layer 55 and the third LED lead frame 50.

In some examples, the resin protective layer 56 is, but not limited to, a silicone resin layer, and the encapsulation gel layer 57 is, but not limited to, a silicone gel layer. The oxygen and moisture permeability of the silicone resin layer is lower than that of the silicone gel layer, and the thermal stress of the silicone resin layer is greater than that of the silicone gel.

Optionally, the third LED lead frame 50 includes a bottom plate 51, an isolation part 52, and a dam part 53 disposed on the bottom plate 51 and surrounding the LED chip. The bottom plate 51 has a functional zone exposed to the dam part, and a portion of the isolation part 52 is exposed to the dam part 53, dividing the functional zone into a larger first functional zone 511 and a smaller second functional zone 512. The LED chip 54 is placed on the larger first functional zone 511, which enhances heat dissipation for the LED chip 54. The LED device includes a first bonding wire 58, with one end connected to the second functional zone 512 of the bottom plate 51 and the other end connected to the LED chip 54. An encapsulation gel layer 57 covers the LED chip 54 and the first bonding wire 58. The encapsulation gel layer 57 with low thermal stress (such as silicone or silicone resin) and a resin protective layer 56 with low oxygen and moisture permeability (such as epoxy resin adhesive) are incorporated in the LED device, specifically, the encapsulation gel layer 57 with low thermal stress covers the first bonding wire 58, while the resin protective layer 56 with low oxygen and moisture permeability covers the LED chip 54 and the junction between the LED chip 54 and the third LED lead frame 50. Accordingly, the encapsulation gel layer 57 with low thermal stress reduces the stress exerted on the first bonding wire 58 when heated, meaning the junction between the first bonding wire 58 and the LED chip 54 or between the first bonding wire 58 and the third LED lead frame 50 experiences less thermal stress, thereby lowering the risk of the first bonding wire 58 being pulled apart by stress. Simultaneously, the resin protective layer 56 with low oxygen and moisture permeability prevents delamination at the junction between the LED chip 54 and the third LED lead frame 50, enhancing the overall structural stability of the LED device and extending its service life.

In some application examples, the LED device can be obtained through, but not limited to, the following steps: the third LED lead frame 50 is fixed onto a platform fixture of a die bonder, the die attach adhesive is applied onto the bottom plate 51 located in the first functional zone 511, and then the LED chip 54 is placed onto the die attach adhesive after dispensing, followed by baking and curing in an oven after die bonding, with the oven temperature set between 100° C. and 200° C., forming the bonding layer 55; the product after die bonding and baking is placed onto a wire bonder platform, one end of the first bonding wire 58 is welded to the electrode of the LED chip 54, and the other end of the first bonding wire 58 is welded to the bottom plate 51 in the second functional zone 512; after wire bonding, resin adhesive is sprayed or dispensed onto the surface of the LED chip 54 and the die attach adhesive, followed by baking in an oven at 80 to 170° C. to form the resin protective layer 56 with a thickness of approximately 10 to 60 μm; after spraying and baking, a dispenser is used to apply the encapsulation gel, followed by baking and curing in an oven at 100 to 160° C. to form the encapsulation gel layer 57; after baking and curing, it is removed for stamping and stripping to obtain a highly reliable LED packaged product.

This embodiment further provides an LED assembly, which may also be referred to as an LED light board. Its application fields can be seen in, but are not limited to, the LED assembly described in Embodiment 1 above. The LED assembly includes a circuit board, which is equipped with the aforementioned LED device.

The LED device and LED assembly provided in this embodiment, compared to the prior art where only encapsulation gel is used to cover the bonding layer between the LED chip and the LED lead frame, introduce the resin protective layer 56 between the encapsulation gel and the LED chip. This layer has lower oxygen and moisture permeability than the encapsulation gel, effectively preventing the bonding layer between the LED chip and the LED lead frame from being easily penetrated by moisture and oxygen, which could reduce bonding strength and cause dead lights. The encapsulation gel covering the resin protective layer can be selected as needed without being restricted by oxygen and moisture permeability. The overall structure of the LED device provided in this embodiment is more stable and has a longer service life.

### Embodiment

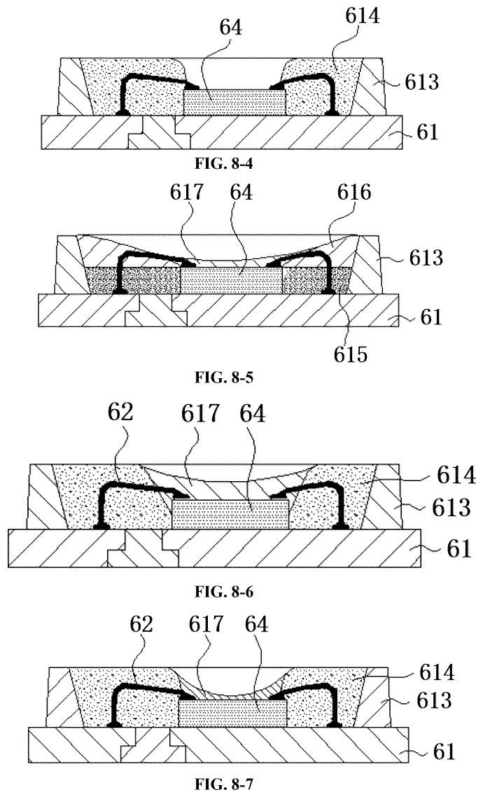

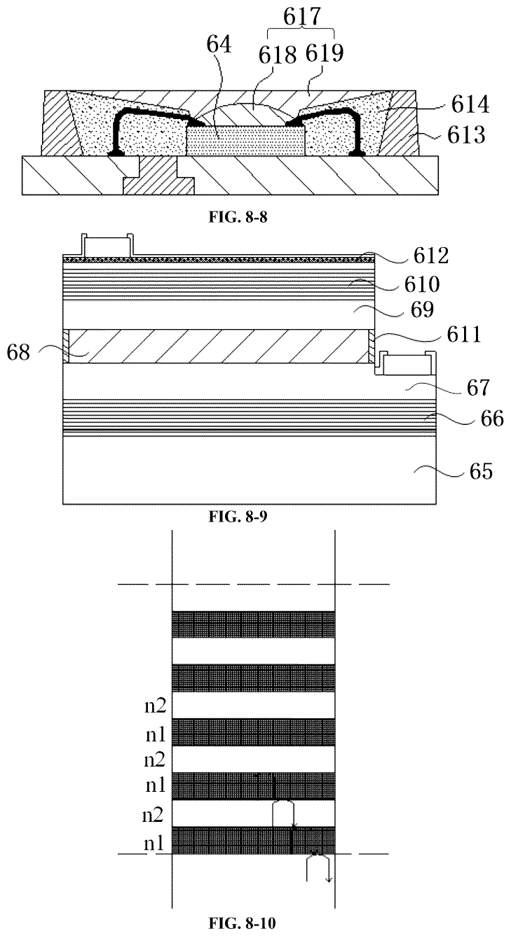

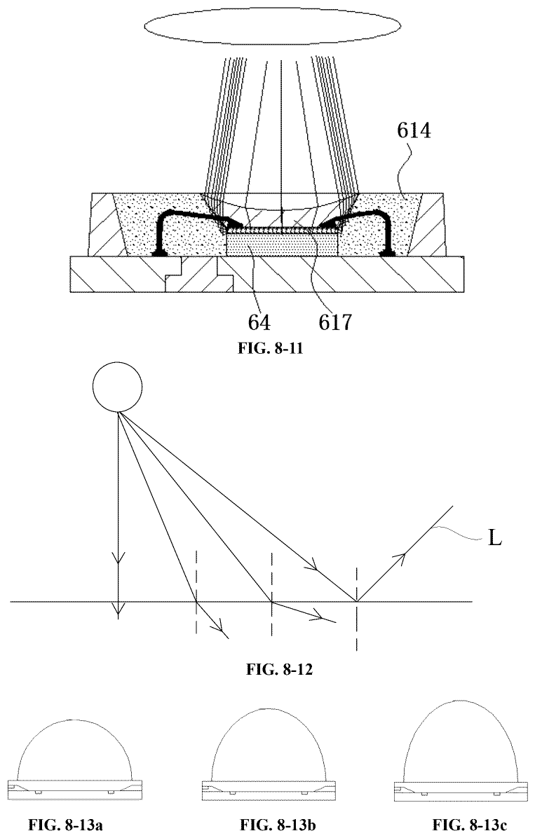

In related art, the irradiance distribution of an LED chip as a point source on the target surface is symmetrical, commonly referred to as the emission angle or radiation angle. The conventional optical angle for optoelectronic packaging structures is around 120°. Traditional narrow-angle optoelectronic devices typically employ lens-based extended light sources, where a curved lens is typically placed above the point source. Generally, a product design with a narrow-beam Lambertian angle can only match a complete set of molding dies. For example, refer to FIGS. 8-13a (an LED device product with an emission angle of) 90°, 8-13b (an LED device product with an emission angle of) 60°, and 8-13b (an LED device product with an emission angle of) 30°, which represent three products with different emission angles, each requiring lenses of different sizes. These lenses are molded using compression or liquid processing methods. For conventional optoelectronic devices with varying narrow-beam angles, if the required emission angle changes during secondary optical design, the lens must be replaced. Moreover, the narrower the required emission angle, the greater the distance from the center of the curved surface of the lens to the light source, resulting in a larger overall device size. Other matching components also need readjustment. Consequently, in devices using lenses for light distribution, a single product series may exhibit multiple sizes, limiting design flexibility. It should also be understood that the LED device in this embodiment can be implemented independently of other embodiments. For clarity, the following provides an illustrative description of this LED device.

Referring to FIGS. 8-1, 8-2, 8-3, and 8-4, the LED device provided in this embodiment includes a third base plate 61, which includes an electrical connector for connecting to a power source. The light-emitting unit of the LED device includes a fourth light-emitting unit 64, which is mounted on the third base plate 61 and electrically connected to the electrical connector. The LED device further includes a reflective gel dam 613 arranged on the third base plate 61, surrounding the fourth light-emitting unit 64 to form an enclosed region. The encapsulation layer includes a reflective gel part 614 located within the enclosed region of the reflective gel dam 613. The reflective gel part 614 contacts the sidewall of the fourth light-emitting unit 64 and avoids at least a portion of the side of the fourth light-emitting unit 64 facing away from the third base plate 61. The reflective gel part 614 forms a cavity region, with the cross-sectional area of the cavity region increasing in the direction away from the third base plate 61. Thus, this embodiment forms a reflective structure by injecting reflective gel into the enclosed region, allowing the design of the structure of the reflective gel part to meet specific light emission angle requirements. During design, only the inner wall structure of the reflective gel needs adjustment, resulting in a light source assembly with advantages such as a narrow beam, compact size, flexible and controllable light pattern design, and high optical energy output. This enables devices of the same series to maintain a uniform appearance and size, facilitating standardized use in applications. A single size can match designs with different narrow-beam optical angles, improving product versatility and increasing design freedom for end products.

In this embodiment, the electrical connector may include a positive connector and a negative connector. In one application example, the fourth light-emitting unit 64 can be bonded or soldered onto the larger of the positive or negative connectors, thereby fixing the fourth light-emitting unit 64 relative to the third base plate 61 via the positive or negative connector. Alternatively, the fourth light-emitting unit 64 can be directly soldered onto the third base plate 61.

In this embodiment, the reflective gel dam 613 is annularly distributed, forming an enclosed region within it, where the fourth light-emitting unit 64 is located. Light waves reflect upon encountering the reflective gel dam 613, and the enclosed region formed by the reflective gel dam 613 serves as a processing and installation area.

In this embodiment, before arranging the fourth light-emitting unit 64, the reflective gel dam 613 and the third base plate 61 can be integrally formed. The material of the reflective gel dam 613 may be thermoplastic, such as PPA (polyphthalamide), PCT (polycyclohexylenedimethylene terephthalate), etc., or thermosetting plastic, such as EMC (epoxy molding compound), etc. Through processes like injection, die-casting, or molding, the reflective gel dam 613 is bonded to the third base plate 61 made of metal materials like copper. Alternatively, after placing the fourth light-emitting unit 64, the reflective gel dam 613 can be thermoformed on the third base plate 61 using an epoxy resin material containing 10%-30% titanium dioxide particles.

In this embodiment, the fourth light-emitting unit 64 is taken as an example of a light-emitting chip for explanation. It is understandable that in this embodiment, the light-emitting chip serves as the light source. A reflective gel part 614 is arranged within the enclosed region formed by the reflective gel dam 613, applied via a piezoelectric valve pulsed jetting method to coat the reflective gel in the enclosed region between the fourth light-emitting unit 64 and the reflective gel dam 613. The reflective gel part 614 is typically composed of high-reflectance particles and phenyl-based high-refractive-index, high-thixotropic adhesive, ensuring the reflectance of the reflective gel part 614 exceeds 99%. The high-reflectance particles consist of titanium dioxide or zirconium dioxide particles with a content greater than 90%, mixed with materials such as hydrophobic silica powder with a content less than 3%. The phenyl-based high-refractive-index, high-thixotropic adhesive has a refractive index greater than 1.55 and exhibits high viscosity and thixotropic properties. With a viscosity of 10,000 mPa·s, the reflective gel part 614 can be directly formed in the enclosed region via piezoelectric valve pulsed jetting without the need for molds, effectively maintaining its shape within the enclosed region. By varying the dispensing patterns of the surrounding jetting, the desired shape of the reflective gel part 614 can be achieved, enabling the design of reflective surfaces at different angles to form the required viewing angles. For example, after baking and curing, shapes as shown in FIGS. 8-3 and 8-4 are obtained. The reflective gel part 614 surrounds the sides of the light source while avoiding at least a portion of the side facing away from the third base plate 61, forming a cavity region. The cross-sectional area of the cavity region increases in the direction away from the third base plate 61, meaning the inner wall of the reflective gel part 614 and the light source surface form an obtuse angle. This ensures that light emitted by the light source is better reflected toward a target receiving plane upon reaching the surface of the reflective gel part 614, improving light reception on the target plane. The reflective gel part 614 is formed within the enclosed region of the reflective gel dam. During the product design phase, if the required viewing angle needs adjustment, only the angle between the reflective gel part 614 and the light source surface needs to be modified to achieve the desired viewing angle, without altering the overall product dimensions. This ensures good dimensional consistency within the same series of devices (devices using the same light source with only adjusted viewing angles are referred to as the same series). Since this embodiment forms the reflective structure by injecting reflective gel into the enclosed region, the structure of the reflective gel part 614 can be designed according to usage requirements. This results in light source assemblies with advantages such as narrow beams, compact size, freely controllable light pattern design, and high optical energy output. The same series of devices can maintain a uniform appearance and size, enabling standardized use at the application end. One size can match designs with different narrow-beam optical angles, enhancing product versatility and increasing design flexibility for end products.

Referring to FIGS. 8-5, in some examples, the reflective gel part 614 includes: a first gel layer 615, located on the side of the fourth light-emitting unit 64 and surrounding the fourth light-emitting unit 64; a second gel layer 616, disposed on the first gel layer 615, which encloses to form a cavity region. In one embodiment, the viscosity of the second gel layer 616 is greater than that of the first gel layer 615.

To achieve better light emission and reduce process difficulty, in some examples of this embodiment, the prepared high-reflectivity adhesive can be applied within the enclosed region between the fourth light-emitting unit 64 and the reflective gel dam 613 using a piezoelectric valve pulse jet method, forming the first gel layer 615. The cured first gel layer 615 has a height close to but not exceeding that of the fourth light-emitting unit 64. The high-reflectivity adhesive used for the first gel layer 615 has high reflectivity and covers the side of the fourth light-emitting unit 64, minimizing light emission from the side and enhancing frontal light output. Typically, to better coat the light source's side, this adhesive requires some fluidity. Another high-reflectivity adhesive is injected onto the hardened first gel layer 615 to form the second gel layer 616. Here, this adhesive is a single-component paste with better thixotropy and viscosity, allowing better shape control through dispensing for improved wave angle management.

Referring to FIGS. 8-2 to 8-7, in some examples, the LED device further includes: a transparent gel 617 covering the side of the fourth light-emitting unit 64 opposite to the third base plate 61. The transparent gel 617 is located within the cavity region, and its side facing away from the fourth light-emitting unit 64 features a concave surface.

Placing the transparent gel 617 with a concave surface above the fourth light-emitting unit 64 protects its top surface and provides a medium for light refraction. In other embodiments, if the fourth light-emitting unit 64 is a vertical or flip-chip LED, requiring electrical connection via bonding wires (i.e., the second bonding wire 62) to the electrical connector 63, the transparent gel 617 also safeguards the electrical connection structure of the fourth light-emitting unit 64.

Optionally, a transparent phenyl high-refractive-index adhesive can be configured. Before formal dispensing, processes such as plasma cleaning can be employed to clean the surface of the reflective gel part 614 using hydrogen and inert argon gas through oxidation or physical bombardment, thereby enhancing the bonding strength between the transparent gel 617 and the reflective gel part 614. The transparent gel 617 is dispensed directly above the fourth light-emitting unit 64, forming a concave surface on the side of the transparent gel 617 facing away from the fourth light-emitting unit 64. Based on the preliminary light distribution design, dispensing can create the desired concave shape, which, combined with the high-reflectivity surfaces of the reflective gel part 614 at different angles, achieves the intended viewing angle. In this embodiment, the concave transparent gel 617 is used for light refraction and focusing, collecting edge light rays to enhance the axial light intensity.

As shown in FIG. 8-8, in some examples, the transparent gel 617 includes: a reinforcement gel layer 618, covering the side of the fourth light-emitting unit 64 facing away from the third base plate 61, with the side of the reinforcement gel layer 618 facing away from the fourth light-emitting unit 64 forming a raised arc-shaped surface; and a protective gel layer 619, covering the surface of the reinforcement gel layer 618, where the reinforcement gel layer 618 is positioned between the protective gel layer 619 and the fourth light-emitting unit 64.

During the adhesive dispensing process, the first step involves dispensing adhesive onto the fourth light-emitting unit 64, covering its top surface to form a reinforcement gel layer 618. Under the surface tension of the gel, the reinforcement gel layer 618 maintains a raised arc-shaped surface without adhesive overflow. After brief baking, the reinforcement gel layer 618 is cured. The convex arc-shaped surface of the reinforcement gel layer 618 protects the top surface of the fourth light-emitting unit 64 and provides an exit for light emission. Next, the prepared reflective gel part 614 is applied via piezoelectric valve pulse jetting into the enclosed region between the fourth light-emitting unit 64 and the reflective gel dam 613, forming the reflective gel part 614. The reflective gel part 614 is higher than the fourth light-emitting unit 64 but does not cover the reinforcement gel layer 618. After brief baking, it is cured. Then, a layer of high-refractive-index transparent adhesive is dispensed over the reinforcement gel layer 618, and is finally baked for curing and forming. The arc-shaped surface above the reinforcement gel layer 618 supports the emission surface, preventing the reflective gel part 614 from obstructing the waves from the front of the fourth light-emitting unit 64. The reflective gel part 614 covers the side surfaces of the fourth light-emitting unit 64 and forms an angle with the surface of the fourth light-emitting unit 64, creating a light-emitting structure of a specific shape around the smooth arc-shaped surface of the reinforcement gel layer 618, thereby meeting narrow-angle requirements.

In one example, the fourth light-emitting unit 64 in this embodiment is a narrow-beam optoelectronic device, including: a light-emitting chip that emits visible light signals or an emission source that emits invisible light signals, where the emission source can be a light-emitting chip that emits invisible light signals. For ease of understanding, the following description uses the fourth light-emitting unit 64 as an LED chip emitting visible light signals as an example. As shown in FIGS. 8-9 and 8-10, the LED chip includes: a substrate 65, placed on the third base plate 61; a first distributed Bragg reflector 66, placed on the substrate 65; a first gallium nitride layer 67, placed on the first distributed Bragg reflector 66, with the first distributed Bragg reflector 66 located between the substrate 65 and the first gallium nitride layer 67; a multiple quantum well layer 68, placed on the first gallium nitride layer 67, with the first gallium nitride layer 67 located between the first distributed Bragg reflector 66 and the multiple quantum well layer 68; a second gallium nitride layer 69, placed on the multiple quantum well layer 68, with the multiple quantum well layer 68 located between the first gallium nitride layer 67 and the second gallium nitride layer 69; and a second distributed Bragg reflector 610, placed on the second gallium nitride layer 69, with the second gallium nitride layer 69 located between the multiple quantum well layer 68 and the second distributed Bragg reflector 610.

To achieve better narrow-angle high-efficiency light output, the LED chip configured in this embodiment is a narrow-angle chip, with the LED chip's viewing angle≤90°.

In the LED chip of this embodiment, distributed Bragg reflectors with a multilayer structure are arranged on both sides of the first gallium nitride layer 67 and the second gallium nitride layer 69 away from the multiple quantum well layer 68. The design of the distributed Bragg reflector consists of alternating thin-film layers of materials with different high and low refractive indices. In this embodiment, it consists of alternating ultra-thin silicon dioxide and titanium dioxide materials, with each layer's thickness being ¼ of the central optical wavelength. The first distributed Bragg reflector 66 serves as the emission layer, with approximately 30-40 layer pairs, achieving an overall reflectivity of about 99.9%. According to the reflection principle, when light travels from an optically rarer medium n1 to an optically denser medium n2 (refractive index n2>n1), the reflected light undergoes a half-wave loss at the interface, causing a phase change and thereby altering the light's refraction path. When light enters the first distributed Bragg reflector 66, it reflects once at each interface between layers. Based on the design principle of the first distributed Bragg reflector 66, a pair of distributed Bragg reflector layers ensures that the twice-reflected light is in phase, enhancing superposition and increasing the overall reflection coefficient. The second distributed Bragg reflector 610 serves as a light-suppressing layer, with approximately 20-30 layer pairs, utilizing the grating refraction principle of distributed Bragg reflectors. Light slows down in higher-refractive-index media and speeds up in lower-refractive-index media. By leveraging this grating characteristic, the reflection efficiency and angle of light can be controlled. Through the configuration of the first distributed Bragg reflector 66 and the second distributed Bragg reflector 610, the first distributed Bragg reflector 66 achieves a mirror-like effect while controlling the emission angle of light, whereas the second distributed Bragg reflector 610 primarily suppresses light and adjusts its emission angle.

As shown in FIGS. 8-9, in some examples, the light-emitting chip may further include: an oxidized mirror layer 611, which surrounds the multiple quantum well layer 68.

To further restrict the light emission angle of the light-emitting chip and achieve a smaller viewing angle, an oxidized mirror layer 611 is also arranged on the side of the multiple quantum well layer 68. The oxidized mirror layer 611 is typically made of aluminum oxide, obtained through a wet oxidation process, and is used to limit sidewall light emission while enhancing axial light output.

As shown in FIGS. 8-9, in some examples, the light-emitting chip further includes: an anti-reflective coating 612, positioned on the second distributed Bragg reflector 610, with the second distributed Bragg reflector 610 located between the second gallium nitride layer 69 and the anti-reflective coating 612.

Referring to FIGS. 8-9 and 8-12, label L denotes the propagation path of total internal reflection light. To enhance light extraction efficiency and reduce total internal reflection, an anti-reflective coating 612 is applied to the light-emitting surface layer above the second distributed Bragg reflector 610. This layer features a patterned surface microstructure directly fabricated on the light-emitting chip's surface, altering the interface geometry between the surface of the light-emitting chip and air to increase the critical angle for total reflection, thereby minimizing total internal reflection and improving light extraction efficiency. These process configurations aim to achieve a light-emitting chip with narrow-beam, high-efficiency output. It should also be noted that narrow-angle, high-efficiency chips are not limited to the exemplified wire-bonded chip; the anti-reflective coating yields equivalent or superior effects in vertical chips and flip-chips.

As shown in FIG. 8-11, prior to finalizing the optical design, Monte Carlo ray tracing simulations are typically employed. Light emitted from the edges of the source is adjusted by the optical system to illuminate the periphery of the target plane. Rays originate from randomly selected points on the light source surface and propagate randomly through space, undergoing reflection, refraction, or total internal reflection upon encountering optical media. In simulations, each emitted ray carries specific luminous energy determined by the source's properties. During propagation, this energy is modified according to losses (e.g., absorption, Fresnel loss) within the optical system. Statistical analysis of all rays on the designated receiver plane yields the luminous energy distribution. The structure of the reflective gel part 614 is designed based on application requirements, validated through multi-scheme experiments to develop preparation methods for various narrow-beam configurations, ultimately producing diverse narrow-beam optoelectronic devices.

This embodiment proposes a first manufacturing method for the aforementioned

LED device, including:
S301: preparing a third base plate;
S302: arranging a fourth light-emitting unit on the third base plate;
S303: forming a reflective gel dam on the third base plate to encircle the fourth light-emitting unit, creating an enclosed region;
S304: injecting reflective gel into the enclosed region of the reflective gel dam to form a reflective gel part.

This embodiment further proposes a second manufacturing method for the aforementioned LED device, including:
S401: preparing a third base plate pre-formed with a reflective gel dam that defines an enclosed region;
S402: arranging a fourth light-emitting unit on the third base plate within the enclosed region formed by the reflective gel dam; and
S403: injecting reflective gel into the enclosed region of the reflective gel dam to form a reflective gel part within the enclosed region.

In the two manufacturing methods for LED devices described in the above examples, the reflective gel dam is arranged around the fourth light-emitting unit to form an enclosed region. The reflective gel part contacts the sidewall of the fourth light-emitting unit and avoids at least a portion of the side facing away from the third base plate. The reflective gel part encloses a cavity region, and the cross-sectional area of the cavity region increases in the direction away from the third base plate.

In the two manufacturing methods for LED devices described in the above examples, reflective gel is injected into the enclosed region, and after the gel is cured, a reflective gel part is formed within the enclosed region. The reflective gel is applied using a piezoelectric valve pulse jetting method to coat the enclosed region between the fourth light-emitting unit and the reflective gel dam. The reflective gel part surrounds the side of the fourth light-emitting unit and forms an angle with its surface, ensuring that light waves emitted by the fourth light-emitting unit are better reflected toward the target receiving plane upon reaching the surface of the reflective gel part, thereby improving light reception on the target plane. The reflective gel part typically consists of high-reflectance particles and phenyl-based high-refractive-index, high-thixotropic adhesive, achieving a reflectance greater than 99%. The high-reflectance particles are a mixture of titanium dioxide or zirconium dioxide particles (content >90%) and hydrophobic silica powder (content <3%). The phenyl-based high-refractive-index, high-thixotropic adhesive has a refractive index greater than 1.55 and exhibits high viscosity and thixotropy, maintaining the configured reflective gel part's shape within the enclosed region. The desired shape of the reflective gel part can be formed by varying the jetting points, allowing the design of reflective surfaces at different angles—for example, achieving the shapes shown in FIGS. 8-3 and 8-4 after baking and curing. The reflective gel part can reflect or refract light waves, thereby controlling the radiation angle of the waves.

Since the reflective structure in this embodiment is formed by injecting reflective gel into the enclosed region, the design of the reflective gel part can be tailored to usage requirements without the need for separate mold injection molding. This results in LED devices with advantages such as narrow beam angles, compact size, freely controllable light patterns, and high optical energy output. Additionally, products with different narrow beam angles can maintain a uniform size specification for standardized application use, where one size can match designs for various designs of narrow beam optical angles, enhancing product versatility.

In some examples, injecting reflective gel into the enclosed region of the reflective gel dam includes: applying a first gel layer on the third base plate, where the first gel layer is located on the side of the fourth light-emitting unit and surrounds the fourth light-emitting unit; after the first gel layer has cured, applying a second gel layer over the first gel layer, where the viscosity of the second gel layer is higher than that of the first gel layer.

To achieve better light emission and reduce process difficulty, the prepared high-reflectivity gel can be applied using a piezoelectric valve pulse-jet method into the enclosed region between the fourth light-emitting unit and the reflective gel dam. The cured first gel layer has a height close to, but not exceeding, that of the fourth light-emitting unit. After the high-reflectivity gel is cured to form the first gel layer, a plasma cleaning process prepares the surface for the next high-reflectivity adhesive bonding. A second layer of high-reflectivity adhesive is then applied over the hardened first gel layer to form the second gel layer. This high-reflectivity adhesive is a single-component paste with superior thixotropy and viscosity, allowing better shape control through dispensing methods to optimize wave emission angles.

In the first manufacturing method described above, the reflective gel dam can be integrally formed with the third base plate. The material of the reflective gel dam may be thermoplastic, such as PPA (polyphthalamide) or PCT (polycyclohexylenedimethylene terephthalate), or thermosetting plastic, such as EMC (epoxy molding compound). Processes like injection, die-casting, or compression molding bond the reflective gel dam to the third base plate made of metal materials like copper. In the second manufacturing method, after placing the fourth light-emitting unit, an epoxy gel containing 10%-30% titanium dioxide particles is used to thermoform the reflective gel dam on the third base plate. This approach allows flexible design of the fourth light-emitting unit's dimensions while eliminating additional costs for third base plate mold fabrication.

In some examples, after injecting reflective gel into the enclosed region of the reflective gel dam, the process further includes: plasma-cleaning the inner wall of the cavity region, then injecting transparent gel into the cavity region to cover the side of the fourth light-emitting unit opposite the third base plate. The end surface of the transparent gel opposite the fourth light-emitting unit forms a concave surface.

A concave lens-like structure is configured above the fourth light-emitting unit to protect the electrical connection lines of the fourth light-emitting unit while also providing light refraction. Specifically, transparent phenyl high-refractive-index adhesive is applied. Before formal dispensing, a plasma cleaning process is employed, using hydrogen and inert argon gas to clean the surface of the reflective gel part through oxidation or physical bombardment, thereby enhancing the bonding strength between the transparent gel and the reflective gel part. The transparent gel is dispensed directly above the fourth light-emitting unit, forming a concave surface on the side facing away from the light-emitting unit. Based on the preliminary optical design, dispensing can create the desired concave shape, which, when paired with the high-reflective surfaces of the reflective gel part at different angles, achieves the intended viewing angle. Different reflective surfaces combined with varying concave shapes can produce the required optical angles. The concave transparent gel refracts and focuses light, collecting edge rays and enhancing the axial light intensity.

In some examples, injecting transparent gel into the enclosed region includes: after placing the fourth light-emitting unit and before injecting the reflective gel, dispensing reinforcement adhesive into the enclosed region to form a reinforcement gel layer on the side of the fourth light-emitting unit facing away from the third base plate, with the side of the reinforcement gel layer facing away from the fourth light-emitting unit forming a raised arc-shaped surface; then injecting the reflective gel into the enclosed region to form a reflective gel part, which contacts the sidewalls of the fourth light-emitting unit while avoiding at least a portion of the side facing away from the third base plate, so that the reflective gel part encloses to form a cavity region; and injecting transparent adhesive into the cavity region to form a protective gel layer over the reinforcement gel layer.

Optionally, dispensing is first performed on the fourth light-emitting unit to form a reinforcement gel layer, which maintains an arc-shaped surface without adhesive overflow. The adhesive is briefly baked and then cured. Next, the prepared reflective gel is coated within the enclosed region between the fourth light-emitting unit and the reflective gel dam using a piezoelectric valve pulse-jet method, forming a reflective gel part. The reflective gel part is higher than the fourth light-emitting unit and intersects with the arc-shaped surface of the reinforcement gel layer. After brief baking, it is cured. A layer of high-refractive-index transparent adhesive is then dispensed over the reinforcement gel layer, and finally baked for curing and forming. The arc-shaped surface above the reinforcement gel layer provides support for the emission surface, preventing the reflective gel part from obstructing the light waves from the front of the fourth light-emitting unit. The reflective gel part covers the sides of the fourth light-emitting unit and forms an angle with its surface, creating a light-emitting structure with a specific shape around the smooth arc-shaped surface, thereby achieving the desired narrow-angle requirement.

This embodiment further provides an LED component, which includes a circuit board equipped with the aforementioned LED device. In addition to the fields mentioned in Embodiment 1 for the LED component, it can also be applied to various optical signal fields, enabling various tests or controls based on visible or invisible light signals emitted by the LED component, which will not be elaborated here.

It should be understood that each of the above embodiments of the present application can be implemented independently or in combination with some embodiments or partial technical features from them. The application of this invention is not limited to the examples provided. For those skilled in the art, improvements or modifications can be made based on the above descriptions, all of which should fall within the protection scope of the appended claims.

1-10. (canceled)

11. An LED device, comprising:
at least seven blue light LED chips;
a packaging layer covering the blue light LED chips, allowing light emitted by the blue light LED chips to pass through the packaging layer,
wherein the blue light LED chips comprise at least three sets of blue light LED chip units with different peak wavelengths ranging from 415 nm to 470 nm;
a radiant flux of the first blue light LED chip unit is 80% to 120% of that of the second blue light LED chip unit;
a radiant flux of the third blue light LED chip unit is 60% to 100% of that of the second blue light LED chip unit;
a radiant flux of the fourth and sixth blue light LED chip units is 80% to 120% of that of the fifth blue light LED chip unit;
a radiant flux of the seventh blue light LED chip unit is 60% to 100% of that of the fifth blue light LED chip unit.

12. The LED device according to claim 11, wherein the first blue light LED chip unit has a full width at half maximum of 15 nm to 25 nm;
the second blue light LED chip unit and the third blue light LED chip unit have a full width at half maximum of 10 nm to 20 nm;
the fourth blue light LED chip unit has a full width at half maximum of 15 nm to 25 nm; and
the fifth blue light LED chip unit, the sixth blue light LED chip unit and the seventh blue light LED chip unit have a full width at half maximum of 10 nm to 20 nm.

13. The LED device according to claim 11, wherein the encapsulation layer comprises a first phosphor gel covering the blue light LED chip units, the first phosphor gel comprising a first phosphor, the first phosphor comprising first cyan phosphor, first green phosphor, first yellow phosphor, and first red phosphor.

14. The LED device according to claim 13, wherein the first cyan phosphor has an emission peak wavelength of 490 nm to 510 nm under blue light excitation, the first green phosphor has an emission peak wavelength of 520 nm to 540 nm under blue light excitation, the first yellow phosphor has an emission peak wavelength of 570 nm to 590 nm under blue light excitation, and the first red phosphor has an emission peak wavelength of 650 nm to 660 nm under blue light excitation;

15. The LED device according to claim 14, wherein the first cyan phosphor has a full width at half maximum of 30 nm to 40 nm under blue light excitation, the first green phosphor has a full width at half maximum of 95 nm to 115 nm under blue light excitation, the first yellow phosphor has a full width at half maximum of 40 nm to 70 nm under blue light excitation, and the first red phosphor has a full width at half maximum of 80 nm to 100 nm under blue light excitation;

16. The LED device according to claim 15, wherein when a color temperature of the LED device is 1700K to 3000K, a mass ratio of the first phosphor to the first encapsulant is 1:1 to 2:1; when the color temperature of the LED device is 4000K, the mass ratio of the first full-spectrum phosphor to the first encapsulant is 1:2 to 1:1;
when the color temperature of the LED device is 5000K, 5700K or 6500K, the mass ratio of the first phosphor to the first encapsulant is 1:3 to 1:1; and when the color temperature of the LED device is 13000K, the mass ratio of the first full-spectrum phosphor to the first encapsulant is 1:5 to 1:2;

17. The LED device according to claim 16, wherein the LED device further comprises a first base plate, with each of the blue LED chip units placed on a same side of the first base plate, and the first phosphor gel applied on the first base plate to cover all the blue LED chip units.

18. The LED device according to claim 16, wherein the LED device further comprises a first LED bracket, the first LED bracket comprises a first reflector cup, and each of the blue light LED chip units is disposed in the first reflector cup, wherein the first phosphor gel is filled in the first reflector cup.

19. The LED device according to claim 16, wherein when the color temperature of the LED device is 1700K, a proportion of the first cyan phosphor is 0% to 5%, a proportion of the first green phosphor is 75% to 85%, a proportion of the first yellow phosphor is 0% to 5%, and a proportion of the first red phosphor is 10% to 20%;
when the color temperature of the LED device is 2700K, the proportion of the first cyan phosphor is 0% to 10%, the proportion of the first green phosphor is 75% to 90%, the proportion of the first yellow phosphor is 0% to 5%, and the proportion of the first red phosphor is 5% to 15%;
when the color temperature of the LED device is 3000K, the proportion of the first cyan phosphor is 0% to 10%, the proportion of the first green phosphor is 75% to 90%, the proportion of the first yellow phosphor is 0% to 5%, and the proportion of the first red phosphor is 10% to 20%;
when the color temperature of the LED device is 4000K, the proportion of the first cyan phosphor is 0% to 10%, the proportion of the first green phosphor is 75% to 95%, the proportion of the first yellow phosphor is 0% to 5%, and the proportion of the first red phosphor is 5% to 15%;
when the color temperature of the LED device is 5000K, the proportion of the first cyan phosphor is 5% to 15%, the proportion of the first green phosphor is 75% to 85%, the proportion of the first yellow phosphor is 0% to 5%, and the proportion of the first red phosphor is 5% to 15%;
when the color temperature of the LED device is 5700K or 13000K, the proportion of the first cyan phosphor is 5% to 15%, the proportion of the first green phosphor is 80% to 90%, the proportion of the first yellow phosphor is 0% to 5%, and the proportion of the first red phosphor is 5% to 15%;
when the color temperature of the LED device is 6500K, the proportion of the first cyan phosphor is 10% to 20%, the proportion of the first green phosphor is 70% to 80%, the proportion of the first yellow phosphor is 0% to 5%, and the proportion of the first red phosphor is 5% to 15%.

20. The LED device according to claim 11, further comprising an eighth blue light LED chip unit and a ninth blue light LED chip unit;
the blue light LED chip unit consists of an eighth blue light LED chip unit and a ninth blue light LED chip unit that are electrically connected, and an emission peak wavelength of the eighth blue light LED chip unit is less than that of the ninth blue light LED chip unit; and
the eighth blue light LED chip unit has a peak wavelength range of 432 nm to 442 nm, and the ninth blue light LED chip unit has a peak wavelength range of 453 nm to 463 nm; and
a radiant flux of the ninth blue light LED chip unit is 60% to 100% of that of the eighth blue light LED chip unit.

21. The LED device according to claim 20, wherein t the eighth blue light LED chip unit has a full width at half maximum of 15 nm to 25 nm, and 4 the ninth blue light LED chip unit has a full width at half maximum of 10 nm to 20 nm.

22. The LED device according to claim 11, wherein the LED device further comprises a third LED lead frame, the light-emitting units comprise a third light-emitting unit consisting of LED chips, and the third LED lead frame has a chip mounting area; the LED device further comprises a bonding layer disposed in the chip mounting area, and the LED chips are arranged on the bonding layer; the encapsulation layer comprises a resin protective layer and an encapsulation gel layer, the resin protective layer covers the bonding layer, and the encapsulation gel layer covers the LED chips and the resin protective layer, wherein an oxygen and moisture permeability of the resin protective layer is lower than that of the encapsulation gel layer.

23. The LED device according to claim 16, wherein the resin protective layer further covers a front surface and side surfaces of the LED chips;
the bonding layer has a circular shape, the bonding layer contacts side portions of the LED chips, and peripheral edges of the bottoms of the LED chips are located within the bonding layer;
the resin protective layer is an epoxy resin layer, and the encapsulation gel layer is a silicone gel layer;
the third LED lead frame comprises a bottom plate and an isolation part, as well as a dam part arranged on the bottom plate and surrounding the LED chips; the bottom plate has a functional zone exposed to the dam part, the isolation part is partially exposed to the dam part and divides the functional zone into a first functional zone and a second functional zone, wherein an area of the first functional zone is larger than that of the second functional zone, and the LED chips are arranged in the first functional zone; and
the LED device comprises a first bonding wire, one end of the first bonding wire is connected to the second functional zone of the bottom plate, and the other end of the first bonding wire is connected to the LED chips.

24. The LED device according to claim 11, wherein the LED device further comprises a third base plate, and the third base plate comprises an electrical connector for connecting to a power source;
the light-emitting units comprise a fourth light-emitting unit that emits optical signals, and the fourth light-emitting unit is arranged on the third base plate and electrically connected to the electrical connector;
the LED device further comprises a reflective gel dam arranged on the third base plate, and the reflective gel dam surrounds the fourth light-emitting unit to form an enclosed region;
the encapsulation layer comprises a reflective gel part located within the enclosed region of the reflective gel dam, the reflective gel part contacts a sidewall of the fourth light-emitting unit and avoids at least a portion of a side of the fourth light-emitting unit facing away from the third base plate, thereby forming a cavity region enclosed by the reflective gel part, wherein a cross-sectional area of the cavity region increases in a direction away from the third base plate.

25. The LED device according to claim 23, wherein a viscosity of the reflective gel part is greater than 10,000mPa·s;
the reflective gel part comprises a first gel layer and a second gel layer, wherein the first gel layer is located on a side of the fourth light-emitting unit and surrounds the fourth light-emitting unit; the second gel layer is disposed on the first gel layer, enclosing the cavity region, and a viscosity of the second gel layer is greater than that of the first gel layer.

26. The LED device according to claim 11, wherein the LED device further comprises a light-emitting unit that is a light-emitting chip capable of emitting visible light signals or an emission source emitting invisible light signals;
the light-emitting chip is disposed on the base plate and comprises the following structures:
a substrate disposed on the base plate;
a first distributed Bragg reflector disposed on the substrate;
a first gallium nitride layer disposed on the first distributed Bragg reflector;
a multiple quantum well layer disposed on the first gallium nitride layer;
a second gallium nitride layer disposed on the multiple quantum well layer; and
a second distributed Bragg reflector disposed on the second gallium nitride layer; and
the light-emitting chip further comprises:
an oxidized mirror layer surrounding the multiple quantum well layer for improving lateral reflectivity;
an anti-reflective coating disposed on a surface of the second distributed Bragg reflector, with the second distributed Bragg reflector located between the second gallium nitride layer and the anti-reflective coating, for enhancing light extraction efficiency;
the LED device further comprises a reflective gel part consisting of:
a phenyl-based high-refractive-index, high-thixotropic adhesive;
high-reflectance particles, comprising:
a) titanium dioxide particles or zirconium dioxide particles with a content greater than 90%; and
b) hydrophobic silica powder with a content less than 3%.

27. An LED assembly, wherein the LED assembly comprises a circuit board and further comprises the LED device according to claim 11, wherein the LED device is disposed on the circuit board.

28. The LED device according to claim 11, wherein a refractive index of the encapsulation layer has a refractive index of 1.4 to 1.7, and a micro-lens structure array is formed on the surface of the encapsulation layer.

29. The LED device according to claim 27, wherein the LED assembly comprises an encapsulation layer, and the encapsulation layer comprises a first phosphor gel covering the blue light LED chip units, the first phosphor gel comprising a first phosphor, and the first phosphor comprising a first cyan phosphor, a first green phosphor, a first yellow phosphor, and a first red phosphor.

30. The LED device according to claim 29, wherein the first cyan phosphor emits light with a peak wavelength ranging from 490 nm to 510 nm under blue light excitation, the first green phosphor emits light with a peak wavelength ranging from 520 nm to 540 nm under blue light excitation, the first yellow phosphor emits light with a peak wavelength ranging from 570 nm to 590 nm under blue light excitation, and the first red phosphor emits light with a peak wavelength ranging from 650 nm to 660 nm under blue light excitation.
